(19) United States
(12) Patent Application Publication
(10) Pub. No.: US 2025/0390685 A1
(43) Pub. Date: Dec. 25, 2025

(54) ROBUSTNESS ANALYSIS

(71) Applicant: Tencent Technology (Shenzhen) Company Limited, Shenzhen (CN)

(72) Inventor: Di LU, Shenzhen (CN)

(73) Assignee: Tencent Technology (Shenzhen) Company Limited, Shenzhen, GD (CN)

(21) Appl. No.: 19/313,774

(22) Filed: Aug. 28, 2025

Related U.S. Application Data
(63) Continuation of application No. PCT/CN2024/096632, filed on May 31, 2024.

(30) Foreign Application Priority Data
Jul. 14, 2023 (CN) 202310863300.1

(51) Int. Cl. G06F 40/35

(52) U.S. Cl. CPC G06F 40/35

(57) ABSTRACT

An original sample set is acquired, the original sample set includes a plurality of original dialog samples, and each original dialog sample includes a round of dialog having at least two speaking turns from different speakers. The plurality of original dialog samples are reconstructed to obtain at least an adversarial sample set associated with a perturbation attack scope, each original dialog sample is modified according to the perturbation attack scope to reconstruct a modified dialog sample in the adversarial sample set. A first test of a dialog understanding model is performed by using the original sample set to obtain original evaluation data. A second test of the dialog understanding model is performed by using the adversarial sample set to obtain adversarial evaluation data. A robustness analysis result is determined according to a change of the adversarial evaluation data with respect to the original evaluation data.

### RELATED APPLICATIONS

The present application is a continuation of International Application No. PCT/CN2024/096632, filed on May 31, 2024, which claims priority to Chinese Patent Application No. 202310863300.1, filed on Jul. 14, 2023. The entire disclosures of the prior applications are hereby incorporated by reference.

### FIELD OF THE TECHNOLOGY

The present disclosure relates to the field of computer technologies, including techniques of a robustness analysis for a dialog understanding model.

### BACKGROUND OF THE DISCLOSURE

With the development of computer technologies, a natural language processing (NLP) technology employing the computer technologies to analyze, understand, and process natural languages emerges. When the natural language processing technology is applied to a dialog understanding task, a dialog understanding model may be obtained through machine learning.

In related art, transformation is performed on a test sample, and then robustness of the dialog understanding model is evaluated by comparing an understanding accuracy of the dialog understanding model employing the test sample before transformation and the understanding accuracy using the transformed test sample. The foregoing processing manner may cause a great difference between different test samples before and after the transformation, thereby leading to an inaccurate evaluation result of the model robustness.

### SUMMARY

According to embodiments of the present disclosure, a robustness analysis method and apparatus for a dialog understanding model, a computer device, a computer-readable storage medium, and a computer program product are provided.

Some aspects of the disclosure provide a method of robustness analysis for a dialog understanding model. In some examples, an original sample set is acquired, the original sample set includes a plurality of original dialog samples, and each original dialog sample in the plurality of original dialog samples includes a round of dialog having at least two speaking turns from different speakers. The plurality of original dialog samples are reconstructed to obtain at least an adversarial sample set associated with a perturbation attack scope, each original dialog sample in the plurality of original dialog samples is modified according to the perturbation attack scope to reconstruct a modified dialog sample in the adversarial sample set, the perturbation attack scope includes at least one of a current turn scope and a historical turn scope in the at least two speaking turns. A first test of the dialog understanding model is performed by using the original sample set to obtain original evaluation data of the dialog understanding model. A second test of the dialog understanding model is performed by using the adversarial sample set to obtain adversarial evaluation data of the dialog understanding model. A robustness analysis result of the dialog understanding model is determined according to a change of the adversarial evaluation data with respect to the original evaluation data.

Some aspects of the disclosure provide an apparatus that includes processing circuitry configured to perform the method of robustness analysis for a dialog understanding model.

Some aspects of the disclosure also provide a non-transitory computer-readable storage medium storing instructions which when executed by at least one processor cause the at least one processor to perform the method of robustness analysis for a dialog understanding model.

In a first aspect, the present disclosure provides a robustness analysis method for a dialog understanding model, which is performed by a computer device. The method includes: acquiring an original sample set, where the original sample set includes a plurality of original dialog samples, and each round of dialog in each original dialog sample includes at least two speaking turns from different speakers; separately reconstructing each original dialog sample for at least a portion of the speaking turns, to obtain an adversarial sample set matching the original sample set; performing test by taking the original sample set as a test sample to obtain original evaluation data of the dialog understanding model; performing test by taking the adversarial sample set as a test set to obtain adversarial evaluation data of the dialog understanding model; and determining a robustness analysis result of the dialog understanding model according to a change of the adversarial evaluation data relative to the original evaluation data.

In another aspect, the present disclosure further provides a robustness analysis apparatus for a dialog understanding model. The apparatus includes: an acquisition module, configured to acquire an original sample set, where the original sample set includes a plurality of original dialog samples, and each round of dialog in each original dialog sample includes at least two speaking turns from different speakers; a reconstruction module, configured to separately reconstruct each original dialog sample for at least a portion of the speaking turns, to obtain an adversarial sample set matching the original sample set; an original test module, configured to perform testing by taking the original sample set as a test set to obtain original evaluation data of the dialog understanding model; an adversarial test module, configured to perform testing by taking the adversarial sample set as a test set to obtain adversarial evaluation data of the dialog understanding model; and a robustness analysis result determining module, configured to determine a robustness analysis result of the dialog understanding model according to a change of the adversarial evaluation data relative to the original evaluation data.

In another aspect, the present disclosure further provides a computer device. The computer device includes a memory and one or more processors, where the memory has computer-readable instructions stored therein, and the one or more processors, when executing the computer-readable instructions, implement the operations of the method embodiments in the present disclosure.

In another aspect, the present disclosure further provides a computer-readable storage medium (e.g., non-transitory computer-readable storage medium). The computer-readable storage medium has computer-readable instructions stored therein, and the computer-readable instructions, when executed by one or more processors (an example of processing circuitry), implement the operations of the method embodiments in the present disclosure.

In another aspect, the present disclosure further provides a computer program product. The computer program product includes computer-readable instructions, and the computer-readable instructions, when executed by one or more processors, implement the operations of the method embodiments in the present disclosure.

Details of one or more embodiments of the present disclosure are provided in the accompanying drawings and descriptions below. Other features, objectives, and advantages of the present disclosure become apparent from the specification, the drawings, and the claims.

### BRIEF DESCRIPTION OF THE DRAWINGS

FIG. 1 is a diagram of an application environment of a robustness analysis method for a dialog understanding model according to an embodiment.

FIG. 2 is a schematic diagram of a deployment process of a dialog understanding model according to an embodiment.

FIG. 3 is a schematic diagram of a robustness analysis process for a dialog understanding model according to an embodiment.

FIG. 4 is a schematic flowchart of a robustness analysis method for a dialog understanding model according to an embodiment.

FIG. 5 is a schematic diagram of a robustness analysis process for a dialog understanding model according to another embodiment.

FIG. 6 is a schematic flowchart of a robustness analysis method for a dialog understanding model according to another embodiment.

FIG. 7 is a schematic diagram of a robustness analysis result employing a robustness index system array according to an embodiment.

FIG. 8 is a schematic diagram of a robustness analysis result employing a model accuracy according to an embodiment.

FIG. 9 is a schematic diagram of a robustness analysis result obtained in an ablation experiment scenario according to an embodiment;

FIG. 10 is a structural block diagram of a robustness analysis apparatus for a dialog understanding model according to an embodiment.

FIG. 11 is a diagram of an internal structure of a computer device according to an embodiment.

FIG. 12 is a diagram of an internal structure of a computer device according to another embodiment.

### DESCRIPTION OF EMBODIMENTS

The following describes technical solutions in embodiments of this disclosure with reference to the accompanying drawings. The described embodiments are some of the embodiments of this disclosure rather than all of the embodiments. Other embodiments are within the scope of this disclosure.

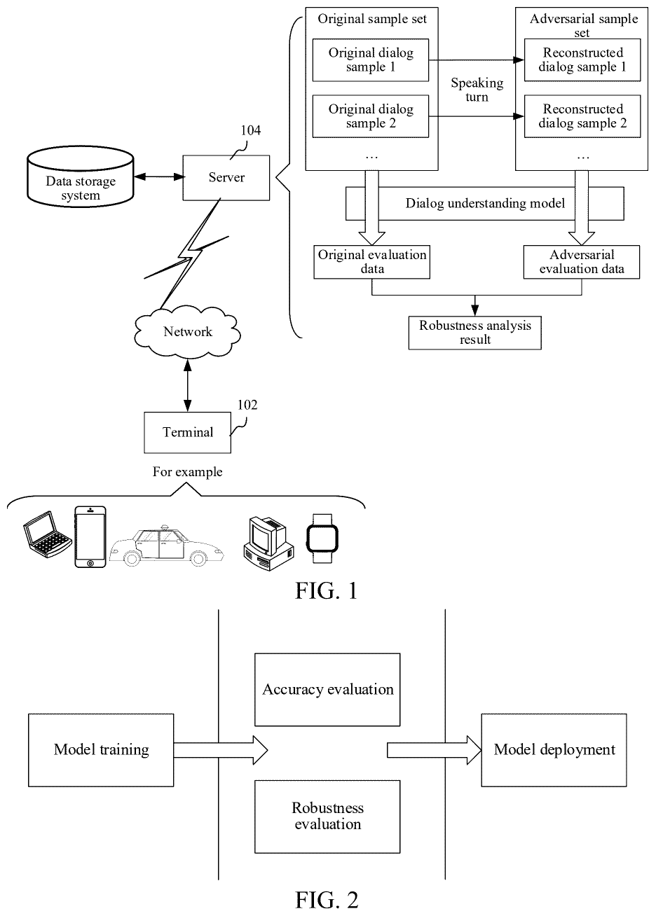

A robustness analysis method for a dialog understanding model provided by the embodiments of the present disclosure may be applied to an application environment shown in FIG. 1. A terminal 102 communicates with a server 104 over a network. The communication network may be a wired network or a wireless network. Therefore, the terminal 102 and the server 104 may be directly or indirectly connected in a wired or wireless communication mode. For example, the terminal 102 may be indirectly connected to the server 104 through a wireless access point, or the terminal 102 may be directly connected to the server 104 through the Internet. This is not limited in this disclosure herein. The terminal 102 may be, but is not limited to, various desktop computers, notebook computers, smartphones, tablet computers, Internet of Things devices, and portable wearable devices. The Internet of Thing device may be a smart speaker, a smart television, a smart air conditioner, a smart in-vehicle device, or the like. The portable wearable device may be a smart watch, a smart band, a head-mounted device, or the like. The server 104 may be an independent physical server, or a server cluster or distributed system including a plurality of physical servers, or may be a cloud server providing basic cloud computing services such as a cloud service, a cloud database, cloud computing, a cloud function, cloud storage, a network service, cloud communication, a middleware service, a domain name service, a security service, a content delivery network (CDN), big data, and an artificial intelligence platform. A data storage system may store data that needs to be processed by the server 104. The data storage system may be configured separately, may be integrated to the server 104, or may be deployed on a cloud or another server.

In addition, the robustness analysis method for the dialog understanding model in the embodiments of the present disclosure may be performed by the server 104 alone, or may be collectively performed by the terminal 102 and the server 104, or may be performed by the terminal 102 alone when a data processing capability of the terminal 102 meets a robustness analysis requirement. Taking an example in which the server 104 performs the method alone, in a robustness analysis process for the dialog understanding model, the server 104 first acquires an original sample set including a plurality of original dialog samples. Each round of dialog in each original dialog sample includes at least two speaking turns from different speakers. Then, each original dialog sample is reconstructed for at least a portion of the speaking turns, to obtain an adversarial sample set matching the original sample set. Next, test is performed by taking the original sample set as a test set to obtain original evaluation data of the dialog understanding model; and test is performed by taking the adversarial sample set as a test set to obtain adversarial evaluation data of the dialog understanding model. Finally, a robustness analysis result of the dialog understanding model is determined according to a change of the adversarial evaluation data relative to the original evaluation data.

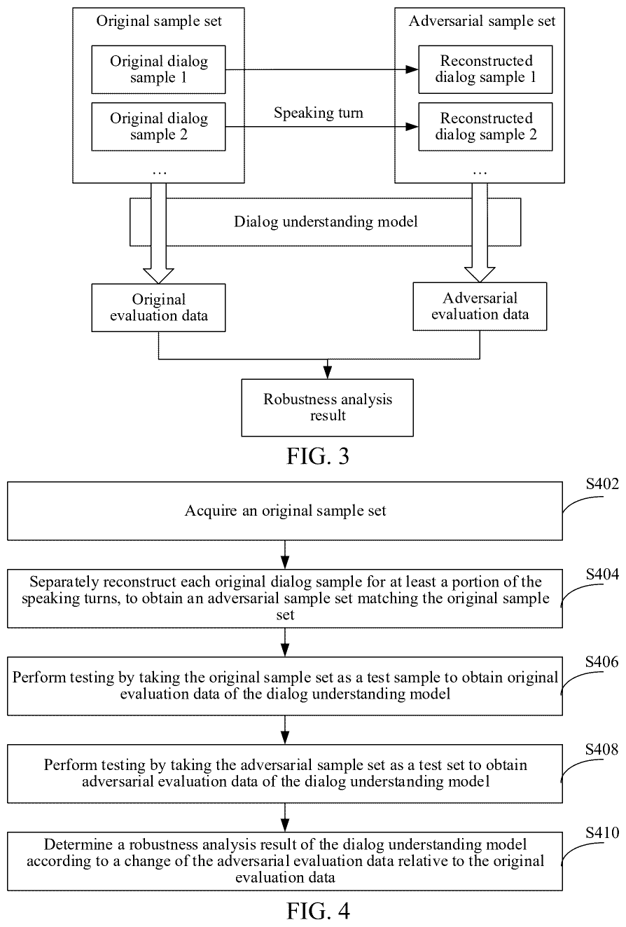

In an embodiment, the robustness analysis method for the dialog understanding model provided by the present disclosure may be applied to an application scenario of robustness evaluation before model deployment. In some aspects, as shown in FIG. 2, after obtaining a dialog understanding model through training, the server needs to perform accuracy and robustness evaluation on the dialog understanding model, to ensure that the model meets application requirements before the model deployment. In a robustness analysis process for the dialog understanding model before the deployment, as shown in FIG. 3, the server may acquire an original sample set including a plurality of original dialog samples, and perform testing by taking the original sample set as a test set to obtain original evaluation data of the dialog understanding model. Each round of dialog in each original dialog sample includes at least two speaking turns from different speakers. Then, the server separately reconstructs each original dialog sample for at least a portion of the speaking turns, to obtain a reconstructed dialog sample matching each original dialog sample, such as a reconstructed dialog sample 1 matching an original dialog sample 1, and a reconstructed dialog sample 2 matching an original dialog sample 2 in FIG. 3. The reconstructed dialog samples form an adversarial sample set matching the original sample set. Next, the server performs the test by taking the adversarial sample set as a test set to obtain adversarial evaluation data of the dialog understanding model. Finally, the server determines a robustness analysis result of the dialog understanding model according to a change of the adversarial evaluation data relative to the original evaluation data. If the robustness analysis result demonstrates that the robustness of the dialog understanding model meets the deployment application requirements, the model is deployed.

In an embodiment, a robustness analysis method for a dialog understanding model provided by the present disclosure may further be applied to a robustness evaluation application scenario for an updated model. In some aspects, in a model application process, updating and iteration are typically required to improve the accuracy. Then, the server may perform robustness analysis on the updated dialog understanding model. For a specific analysis process, refer to the foregoing descriptions, and details are not described herein again. If a robustness analysis result demonstrates that the robustness of the updated dialog understanding model is better than that of the dialog understanding model before the updating, the dialog understanding model before the updating may be replaced with the updated dialog understanding model. On the contrary, if the robustness analysis result demonstrates that the robustness of the updated dialog understanding model is worse than that of the dialog understanding model before the updating, whether it is necessary to perform the model updating at this time needs to be further evaluated with reference to other indexes. The other indexes may include operating efficiency, accuracy, a model size, and the like.

In an embodiment, as shown in FIG. 4, a robustness analysis method for a dialog understanding model is provided, the method may be performed by a computer device, the computer device may be the terminal or the server shown in FIG. 1, and in the present embodiment, taking an example in which the method is applied to the server in FIG. 1, the method includes the following operations:

Operation S402: Acquire an original sample set,
where the original sample set includes a plurality of original dialog samples. A dialog refers to a language communication process in which at least two speakers participate. The original dialog sample refers to text configured for recording a dialog process. A type of language used in the original dialog samples is not unique and may include, for example, Chinese, English, German, etc. This is not limited herein. The original sample set refers to a sample set including a plurality of original dialog samples. Each original dialog sample includes at least one round of dialog, and each round of dialog includes at least two speaking turns from different speakers. Further, the original dialog sample includes speaker information and utterance information. For example, the original dialog sample 1 may be:
“(Speaking turn 1) speaker A: I ate a mango today.
(Speaking turn 2) speaker B: It is very difficult to buy mangoes in this season.
(Speaking turn 3) speaker A: How about I give you a box? I have a lot.
(Speaking turn 4) speaker B: Great!”

The “speaker A” and “speaker B” recorded in the original dialog sample 1 are speaker information, “I ate a mango today”, “It is very difficult to buy mangoes in this season”, “How about I give you a box? I have a lot.”, “Great!” are utterance information, and the original dialog sample 1 includes a total of two rounds of dialogs, and each round of dialog includes two speaking turns in which the speaker A and the speaker B participate. To be specific, the speaking turn 1 and the speaking turn 2 form a round of dialog, and the speaking turn 3 and the speaking turn 4 form a round of dialog. In addition, each round of dialog in the original dialog sample may include a plurality of dialog forms such as a declarative dialog or a question-answer dialog. This is not limited herein. For example, in the original dialog sample 1, a round of declarative dialog is formed by the speaking turn 1 and the speaking turn 2, and a round of question-answer dialog is formed by the speaking turn 3 and the speaking turn 4.

In some aspects, the server may acquire the original sample set including a plurality of original dialog samples. A specific manner for the server to acquire the original sample set may be active acquisition, or passive receiving. For example, a user may input dialog information into a terminal. A specific form of the dialog information may include, for example, voice, words, and the like. Then the server obtains the original dialog sample based on a dialog record formed by the dialog information, and further obtains the original sample set including a plurality of original dialog samples. Alternatively, the server may acquire the original dialog sample set through a network.

Operation S404: Separately reconstruct each original dialog sample for at least a portion of the speaking turns, to obtain an adversarial sample set matching the original sample set.

Robustness may be understood as a tolerance of a model to data changes. Assuming that a small deviation occurring in the sample data or a small perturbation inside the model has only a small impact on a model output and can still generate correct results, the model is said to have withstood the attack and the model is robust. Based on this, for the dialog understanding model, a dialog sample may be reconstructed by adding an imperceptible perturbation, to test the robustness and defects of the dialog understanding model. Imperceptibility of the perturbation in a reconstruction process may be understood as: the added perturbation has relatively little impact on sample semantics.

In some aspects, as described above, each round of dialog in each original dialog sample includes at least two speaking turns from different speakers. To be specific, the original dialog sample is essentially formed by a plurality of speaking turns. Based on this, the server may perform, for at least a portion of the speaking turns, information transformation is performed on utterance information in the portion of the speaking turn in each original dialog sample, to obtain the reconstructed dialog sample matching the original dialog sample, and further obtain the adversarial sample set matching the original sample set.

Further, the process of performing information transformation on the utterance information may include the information transformation at various levels such as a character level, a word level, and a sentence level. The character-level transformation is also referred to as a character granularity attack, and corresponds to English letters or Chinese characters. The reconstructed dialog sample may be generated at the letter or character level by replacing characters with similar form or homophones, and adding the perturbation in a manner of adding, deleting, and changing character granularity. The word-level transformation is also referred to as a word granularity attack, and corresponds to English words or Chinese words. The reconstructed dialog sample may be generated at a level of words or phrases by replacing synonyms, and adding the perturbation in a manner of adding, deleting, and changing the word granularity. The sentence-level transformation is also referred to as a sentence granularity attack, and corresponds to an English sentence or a Chinese sentence, where the perturbation is performed on the sentence level, to generate the reconstructed dialog sample.

In an embodiment, the server may separately reconstruct each original dialog sample for a target speaking turn, satisfying a set condition, of the speaking turns.

The set condition may be, for example, represented by at least one of a reconstruction turn condition, a reconstruction turn quantity condition, and a turn information quantity condition. The reconstruction turn condition indicates a condition that needs to be satisfied by a turn sequence of the target speaking turn in the original dialog sample; a reconstruction turn quantity condition indicates a condition that needs to be satisfied by a quantity of target speaking turns in the original dialog sample; and the turn information quantity condition indicates a condition that needs to be satisfied by an information quantity included in the utterance information corresponding to the target speaking turn. The turn sequence may include, for example, an odd turn and an even turn, and may further include a current turn and historical turns. The current turn is a last speaking turn of the original dialog sample, such as the speaking turn 4 in the original dialog sample 1 described above. The information quantity of the speaking turn may be represented by a total quantity of characters, a quantity of word slots, and the like included in the utterance information of the speaking turn. The quantity of the target speaking turns in an original dialog sample may be one or more.

In an implementation example, the server may perform information transformation on the target speaking turn that satisfies the turn information quantity condition in the speaking turns, to reconstruct the original dialog sample. The turn information quantity condition may be, for example, that the total quantity of characters included in the utterance information of the target speaking turn is greater than a set quantity of characters, or the total quantity of characters is greater than or equal to the set quantity of characters.

In an implementation example, the server may perform the information transformation on the last speaking turn in each original dialog sample, or may perform the information transformation on the first speaking turn in each original dialog sample, or may perform the information transformation on at least a portion of the historical speaking turns other than the last speaking turn in each original dialog sample, to reconstruct the original dialog sample. For example, the reconstructed dialog sample matching the original dialog sample 1 may include a reconstructed dialog sample 1-1 in which the information transformation is performed on all speaking turns, a reconstructed dialog sample 1-2 in which the information transformation is performed only on the last speaking turn, and a reconstructed dialog sample 1-3 in which the information transformation is performed only on the historical speaking turns.

The reconstructed dialog sample 1-1 may be:
“(Speaking turn 1) speaker A: I ate a mango today.
(Speaking turn 2) speaker B: It is [really] very difficult to buy mangoes in this season.
(Speaking turn 3) speaker A: How about I [send] give you a box? I have a lot.
(Speaking turn 4) speaker B: Great [Wonderful]!”

The information transformation is performed on the reconstructed dialog sample 1-1 based on the original dialog sample 1 as follows: a quantifier “a” in the speaking turn 1 is deleted; an adverb “really” is added in the speaking turn 2; the verb “give” in the speaking turn 3 is replaced with “send”; and the adjective “great” in the speaking turn 4 is replaced with “wonderful”.

The reconstructed dialog sample 1-2 may be:
“(Speaking turn 1) speaker A: I ate a mango today.
(Speaking turn 2) speaker B: It is very difficult to buy mangoes in this season.
(Speaking turn 3) speaker A: How about I give you a box? I have a lot.
(Speaking turn 4) speaker B: Great [Wonderful]!”

The information transformation is performed on the reconstructed dialog sample 1-2 based on the original dialog sample 1 as follows: “great” in the speaking turn 4 is replaced with “wonderful”.

The reconstructed dialog sample 1-3 may be:
“(Speaking turn 1) speaker A: I ate a mango today.
(Speaking turn 2) speaker B: It is [really] very difficult to buy mangoes in this season.
(Speaking turn 3) speaker A: How about I [send] give you a box? I have a lot.
(Speaking turn 4) speaker B: Great!”

The information transformation is performed on the reconstructed dialog sample 1-3 based on the original dialog sample 1 as follows: “a” in the speaking turn 1 is deleted; “really” is added in the speaking turn 2; and “give” in the speaking turn 3 is replaced with “send”.

Operation S406: Perform testing by taking the original sample set as a test set to obtain original evaluation data of the dialog understanding model.

The dialog understanding model is a machine learning model configured to implement a dialog understanding task. In some aspects, in the present disclosure, the dialog understanding model is an analysis object for robustness analysis. The dialog understanding task may include, for example, at least one of tasks such as dialog intention understanding or dialog emotion understanding. The dialog intention refers to content information that the speakers in a dialog want to express through the dialog, to convey a particular task requirement. The task requirement may include, for example, movie ticket booking, air ticket booking, music playback, and the like. The dialog emotion refers to emotion information expressed by the speakers during a dialog, and the dialog emotion may include, for example, happiness, neutrality, sadness, and the like. Further, the dialog understanding model, for example, may be a neural network model or a decision tree model, and a specific type of the neural network model is not unique, and may include, for example, a convolutional neural network (CNN) model, a recurrent neural network (RNN) model, or a generative adversarial network (GAN) model. This is not limited herein.

In the practical application, for a given model, an object on which robustness analysis is performed may be the model itself, or may be an adjusted model obtained by processing the model. The adjusted model may, for example, be an updated model obtained by incremental training or an ablation model obtained by removing some components from the model. For example, in an ablation experiment scenario, an impact of different components in the dialog understanding model on a robustness result may be analyzed. In this scenario, the complete dialog understanding model and the ablation dialog understanding model from which a target component is removed may be used as robustness analysis objects, and the impact of the target component on the model robustness is determined according to the robustness analysis results of the complete dialog understanding model and ablation dialog understanding model under the same original sample set and adversarial sample set. For example, the impact result of addition or deletion of different components (R1-R3) in the model M1 on the final robustness may be validated by using a plurality of data sets. In this case, the robustness analysis object includes the complete dialog understanding model M1, a dialog understanding model M1-R1 after a component R1 is removed, a dialog understanding model M1-R2 after a component R2 is removed, and a dialog understanding model M1-R3 after a component R3 is removed.

The original evaluation data is model evaluation data obtained through a test by taking the original sample set as the test set. In the practical application, the dialog understanding model may be tested by using the test set, to obtain the corresponding model evaluation data. The model evaluation data may include, for example, indexes such as a confusion matrix, an area under curve (AUC) area, a receiver operating characteristic (ROC) curve, an error rate, an accuracy, and a loss statistical value. The loss statistical value may include, for example, a loss average value, a standard deviation, a standard score, and the like.

In some aspects, the server may test the dialog understanding model by taking the original sample set as a test set, to obtain original evaluation data of the dialog understanding model. Taking an example in which the original evaluation data is the accuracy, the server may input each original dialog sample into the dialog understanding model, obtain a model output corresponding to each original dialog sample, compare each model output with a corresponding label, obtain, by statistics, a sample ratio of the model outputs matching the label, and then determine the accuracy of the dialog understanding model.

Operation S408: Perform testing by taking the adversarial sample set as a test set to obtain adversarial evaluation data of the dialog understanding model.

In some aspects, after the adversarial sample set is obtained, the server may test the dialog understanding model by taking the adversarial sample set as a test set, to obtain adversarial evaluation data of the dialog understanding model. Taking an example in which the adversarial evaluation data is the accuracy, the server may input each reconstructed dialog sample into the dialog understanding model, obtain a model output corresponding to each reconstructed dialog sample, compare each model output with a corresponding label, obtain, by statistics, a sample ratio of the model outputs matching the label, and then determine the accuracy of the dialog understanding model under the test with the adversarial sample set. The label corresponding to the reconstructed dialog sample is a label of the original dialog sample matching the reconstructed dialog sample.

In addition, the adversarial evaluation data is of the same data type as the original evaluation data. For example, when the original evaluation data includes the accuracy, the adversarial evaluation data further includes the accuracy; and when the original evaluation data includes the loss statistical value, the adversarial evaluation data further includes the loss statistical value, and the like.

Operation S410: Determine a robustness analysis result of the dialog understanding model according to a change of the adversarial evaluation data relative to the original evaluation data.

The change of the adversarial evaluation data relative to the original evaluation data may be represented by a difference, a ratio, or the like. In some aspects, the server may determine the robustness analysis result of the dialog understanding model according to the change of the same type of adversarial evaluation data relative to the original evaluation data.

In an embodiment, the original evaluation data includes an original accuracy, and the adversarial evaluation data includes an adversarial accuracy. In the present embodiment, Operation S410 includes: accuracy change data of the adversarial accuracy relative to the original accuracy is determined; and the robustness analysis result of the dialog understanding model is determined based on the accuracy change data.

The original accuracy refers to a model accuracy determined by taking the original sample set as the test set. Correspondingly, the adversarial accuracy refers to the model accuracy determined by taking the adversarial sample set as the test set. The model accuracy may include at least one of a dialog intention understanding accuracy and a dialog emotion understanding accuracy. In some aspects, the server may determine the accuracy change data of the adversarial accuracy relative to the original accuracy, and determine the robustness analysis result of the dialog understanding model based on the accuracy change data. The accuracy change data may include an accuracy change quantity, an accuracy change rate, and the like.

An example in which the model accuracy is the dialog emotion understanding accuracy is used. The server may determine a correct emotion understanding sample, in which a dialog emotion understanding result matches a dialog emotion label, in the original sample set, and determine a proportion of the correct emotion understanding samples in the original sample set as the original accuracy; and the server may further determine the correct emotion understanding sample, in which the dialog emotion understanding result matches the dialog emotion label, in the adversarial sample set, and determine a proportion of the correct emotion understanding samples in the adversarial sample set as the adversarial accuracy. Then, the robustness analysis result of the dialog understanding model is determined based on a difference between the adversarial accuracy and the original accuracy. If the change of the adversarial accuracy relative to the original accuracy is relatively small, it indicates that the evaluated dialog understanding model has a strong anti-attack capability, and shows strong robustness.

In the present embodiment, the robustness analysis result of the dialog understanding model is determined based on the accuracy change data, which can intuitively reflect the model performance, and is conducive to improving the reliability of the robustness analysis result.

In an embodiment, the original evaluation data includes an original loss statistical value, and the adversarial evaluation data includes an adversarial loss statistical value. In the present embodiment, Operation S408 includes: loss change data of the adversarial loss statistical value relative to the original loss statistical value is determined; and the robustness analysis result of the dialog understanding model is determined based on the loss change data.

The original loss statistical value is a model loss statistical value determined by taking the original sample set as the test set. Correspondingly, the adversarial loss statistical value is a model loss statistical value determined by taking the adversarial sample set as the test set. The model loss statistical value may include at least one of a loss average value, a loss average value, a standard deviation, a standard score, and the like. In some aspects, the server may determine the loss change data of the adversarial loss statistical value relative to the original loss statistical value, and determine the robustness analysis result of the dialog understanding model based on the loss change data. The loss change data may include a loss change quantity, a loss change rate, and the like.

An example in which the model loss statistical value is the loss average value is used. The server may perform statistical calculation on a loss value of each original dialog sample, to obtain the original loss average value of the dialog understanding model under the original sample set, and perform the statistical calculation on the loss value of each original dialog sample to obtain the adversarial loss average value of the dialog understanding model under the original sample set. Then, the robustness analysis result of the dialog understanding model is determined based on a difference between the adversarial loss average value and the original loss average value. If the change of the adversarial loss average value relative to the original loss average value is relatively small, it indicates that the evaluated dialog understanding model has a strong anti-attack capability, and shows strong robustness.

In the present embodiment, the robustness analysis result of the dialog understanding model is determined based on the loss change data, and the algorithm is simple, which is conducive to improving the processing efficiency of the robustness analysis process.

In an embodiment, the original evaluation data includes an original accuracy and an original loss statistical value, and the adversarial evaluation data includes an adversarial accuracy and an adversarial loss statistical value. In the present embodiment, Operation S408 includes: accuracy change data of the adversarial accuracy relative to the original accuracy and loss change data of the adversarial loss statistical value relative to the original loss statistical value are determined; and the robustness analysis result of the dialog understanding model is determined based on the accuracy change data and the loss change data.

For specific limitations to the original accuracy, the original loss statistical value, the adversarial accuracy, and the adversarial loss statistical value, refer to the foregoing descriptions, and details are not described herein again. In some aspects, the server may determine the adversarial accuracy of the dialog understanding model by taking the adversarial sample set as the test set, determine the original accuracy of the dialog understanding model by taking the original sample set as the test set, and obtain the accuracy change data according to the change of the adversarial accuracy relative to the original accuracy. Moreover, the server may further determine the adversarial loss statistical value of the dialog understanding model by taking the adversarial sample set as the test set, determine the original loss statistical value of the dialog understanding model by taking the original sample set as the test set, and obtain the loss change data according to the change of the adversarial loss statistical value relative to the original loss statistical value. Then, the server may determine the accuracy change data and the loss change data as the robustness analysis results of the dialog understanding model, or may obtain the robustness analysis result of the dialog understanding model by further processing the accuracy change data and the loss change data. For example, the server may perform normalization processing on the accuracy change data and the loss change data, and then obtain the robustness analysis result through weighted summation. A weight of the accuracy change data is greater than a weight of the loss change data.

In the present embodiment, the robustness analysis result of the dialog understanding model is determined according to the accuracy change data and the loss change data, which is conducive to further improving the accuracy of the robustness analysis result.

According to the foregoing robustness analysis method for the dialog understanding model, the original sample set including the plurality of original dialog samples is taken as the test set for testing to obtain the original evaluation data of the dialog understanding model; each round of dialog in each original dialog sample includes at least two speaking turns from different speakers; each original dialog sample is reconstructed separately for at least a portion of the speaking turns, to obtain the adversarial sample set matching the original sample set; the test is performed by taking the adversarial sample set as the test set to obtain the adversarial evaluation data of the dialog understanding model; and the robustness analysis result of the dialog understanding model is determined according to the change of the adversarial evaluation data relative to the original evaluation data. During the foregoing processing, in the robustness analysis process for the dialog understanding model, each original dialog sample is reconstructed separately for a portion of the speaking turn based on a particular attribute that each original dialog sample includes a plurality of speaking turns, whereby a difference between different samples before and after the reconstruction can be reduced to some extent, the final robustness analysis result is more credible, and the accuracy of the robustness analysis result is improved. Furthermore, the original sample set including a plurality of original dialog samples and the adversarial sample set matching the original sample set are respectively taken as the test sets, and the robustness analysis result is determined according to the changes of the model evaluation data of the dialog understanding model under different test sets, which is equivalent to combining the robustness of the model under the adversarial test of a plurality of samples, whereby the accuracy of the robustness analysis result can further be improved.

In an embodiment, a quantity of the adversarial sample sets is at least two. In the present embodiment, Operation S406 includes: the test is performed by taking each adversarial sample set as a test set to obtain adversarial evaluation data of the dialog understanding model corresponding to each adversarial sample set. Operation S410 includes: the robustness analysis result of the dialog understanding model is determined according to a change of each piece of adversarial evaluation data relative to the original evaluation data.

Reconstruction parameters of different adversarial sample sets are different. The reconstruction parameters may include a reconstruction turn parameter, a reconstruction granularity parameter, an information transformation manner, and the like. The reconstruction turn parameter is configured for representing a parameter condition that needs to be satisfied by the speaking turn in which the information transformation is performed in a reconstruction process. The reconstruction granularity parameter is configured for representing an information transformation level, and may include a granularity such as a character, a word, and a sentence. The information transformation manner may include deletion, replacement, addition, or the like. The replacement may be pronunciation-similar replacement, character-similar replacement, semantic-similar replacement, or the like. Different reconstruction parameters of different adversarial sample sets are different, which may refer to that at least some parameters such as the reconstruction turn parameter, the reconstruction granularity parameter, or the information transformation manner corresponding to different adversarial sample sets are different. For example, the reconstruction turn parameter of an adversarial sample set A is different from that of an adversarial sample set B, and the reconstruction granularity parameter of the adversarial sample set B is different from that of an adversarial sample set C.

In some aspects, the server may obtain a plurality of reconstruction parameters by combining the parameter information such as the reconstruction turn parameter, the reconstruction granularity parameter, and the information transformation manner. Then, the server performs sample reconstruction on the original sample set according to each reconstruction parameter, to obtain the adversarial sample set corresponding to each reconstruction parameter. Next, the server performs the test by taking each adversarial sample set as the test set to obtain the adversarial evaluation data of the dialog understanding model corresponding to each adversarial sample set, and determines the robustness analysis result of the dialog understanding model according to the change of each piece of the adversarial evaluation data relative to the original evaluation data.

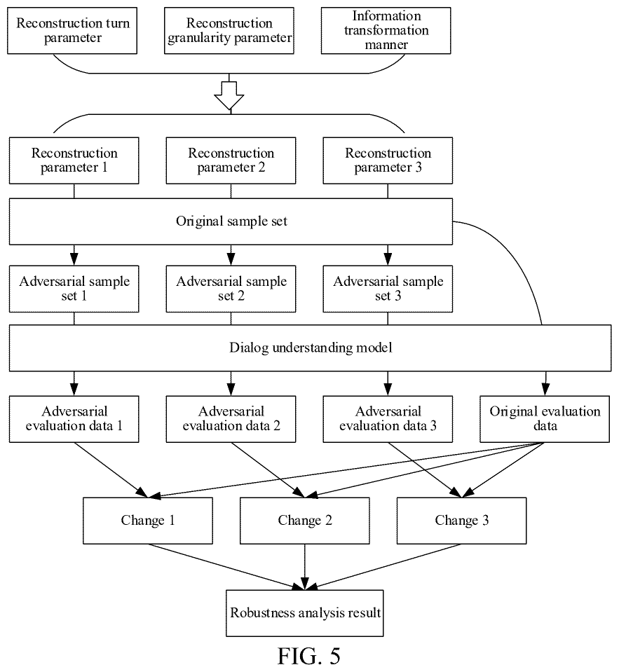

For example, as shown in FIG. 5, the server may obtain a reconstruction parameter 1, a reconstruction parameter 2, and a reconstruction parameter 3 by combining the parameter information. In an implementation example, the reconstruction parameter 1, for example, may be synonym replacement of the word granularity for the last speaking turn; the reconstruction parameter 2, for example, may be homonym replacement of the character granularity for each historical speaking turn; and the reconstruction parameter 3, for example, may be deletion of a modal particle in each speaking turn. Then, the server performs sample reconstruction on the original sample set according to the reconstruction parameter 1, to obtain an adversarial sample set 1, performs the sample reconstruction on the original sample set according to the reconstruction parameter 2, to obtain an adversarial sample set 2, and performs the sample reconstruction on the original sample set according to the reconstruction parameter 3, to obtain an adversarial sample set 3. Subsequently, the server performs the test by taking the adversarial sample set 1 as a test set to obtain adversarial evaluation data 1 of the dialog understanding model corresponding to the adversarial sample set 1, performs the test by taking the adversarial sample set 2 as a test set, to obtain adversarial evaluation data 2 of the dialog understanding model corresponding to the adversarial sample set 2, and performs the test by taking the adversarial sample set 3 as a test set to obtain adversarial evaluation data 3 of the dialog understanding model corresponding to the adversarial sample set 3. Finally, the server determines the robustness analysis result of the dialog understanding model according to the change of each piece of the adversarial evaluation data relative to the original evaluation data obtained by testing with the original sample set as the test set.

Further, the server may determine the change of each piece of the adversarial evaluation data relative to the original evaluation data as the robustness analysis result of the dialog understanding model. On this premise, the obtained robustness analysis result may be configured for representing the robustness of the dialog understanding model in adversarial attack scenarios corresponding to different reconstruction parameters. The server may alternatively perform statistical calculation on the change of each piece of adversarial evaluation data relative to the original evaluation data, to determine the robustness analysis result of the dialog understanding model. On this premise, the obtained robustness analysis result may be configured for representing overall anti-attack performance of the dialog understanding model, namely, comprehensive robustness of the dialog understanding model. A specific algorithm of the statistical calculation may include at least one of addition, multiplication, and the like.

In the present embodiment, performing robustness analysis on each adversarial sample set is equivalent to comprehensively considering the robustness of the dialog understanding model in different adversarial attack scenarios, which is conducive to further improving the accuracy of the robustness analysis result.

In an embodiment, Operation S404 includes: a desired reconstruction turn in the sample reconstruction process is determined; a sample reconstruction turn matching the desired reconstruction turn is determined from the speaking turns of the original dialog sample for each original dialog sample; and sample reconstruction is performed on each original dialog sample according to the sample reconstruction turn of each original dialog sample, to obtain the adversarial sample set matching the original sample set.

The desired reconstruction turn indicates a speaking turn in which information conversion is desired to be performed. The desired reconstruction turn may be determined in multiple manners. For example, the desired reconstruction turn may be determined based on a turn sequence. For example, the desired reconstruction turn may include a current turn and historical turns, or may include a target turn, a previous turn of the target turn, and a subsequent turn of the target turn. The current turn is a last speaking turn in a dialog sample, the historical turn is a speaking turn before the last speaking turn, correspondingly, the previous turn of the target turn is a speaking turn before the target turn, and the subsequent turn of the target turn is a speaking turn after the target turn. In the practical application, the desired reconstruction turn may further be determined with reference to the turn information quantity condition. The information quantity of the speaking turn may be represented by a total quantity of characters, a quantity of word slots, and the like included in the utterance information of the speaking turn. For example, the server may determine the speaking turn, in which the total quantity of characters included in the utterance information is greater than a set quantity of characters or the total quantity of characters is greater than or equal to the set quantity of characters, as the desired reconstruction turn.

In some aspects, the quantity of speaking turns included in each original dialog sample may be different, and the utterance information included in the speaking turn is further different. Based on this, the server may determine the desired reconstruction turn in the sample reconstruction process. The desired reconstruction turn may be directly set by a developer according to a robustness analysis requirement, for example, set as the historical turn or the current turn, or may be determined by the server according to the reconstruction turn condition set by the developer. The reconstruction turn condition may be represented by the turn information quantity, the turn sequence, and the like.

Then, for each original dialog sample, the server determines the sample reconstruction turn matching the desired reconstruction turn from the speaking turns of the original dialog sample. The sample reconstruction turn refers to the speaking turn matching the desired reconstruction turn in the original dialog sample. Taking an example in which the desired reconstruction turn is the current turn, for the original dialog sample including four speaking turns, the sample reconstruction turn of the original dialog sample is the “speaking turn 4”; and for the original dialog sample including five speaking turns, the sample reconstruction turn of the original dialog sample is the “speaking turn 5”. Next, the server performs information transformation on the utterance information in each sample reconstruction turn according to sample reconstruction turn of each original dialog sample to achieve sample reconstruction for each original dialog sample and obtain the adversarial dialog sample matching each original dialog sample, thereby obtaining the adversarial sample set matching the original sample set.

In the present embodiment, the desired reconstruction turn in the sample reconstruction process is determined first, and then the sample reconstruction is performed separately for the sample reconstruction turn matching the desired reconstruction turn in each original dialog sample, whereby the difference between different samples before and after the reconstruction can be further reduced, and the accuracy of the robustness analysis result can be further improved.

In an embodiment, the operation of determining a sample reconstruction turn matching the desired reconstruction turn from the speaking turns of the original dialog sample includes: the last speaking turn of the original dialog sample is determined as the sample reconstruction turn matching the desired reconstruction turn when the desired reconstruction turn includes the current turn; and at least a portion of the historical speaking turns of the original dialog sample are determined as the sample reconstruction turns matching the desired reconstruction turn when the desired reconstruction turn includes the historical turns.

In the practical application, for the dialog understanding model, more attention is typically paid to the performance of the model for the current turn and the performance of the model for the historical turns. Based on this, the desired reconstruction turn may include at least one of the current turn and the historical turns. The sample reconstruction may be performed only for the current turn, or the sample reconstruction may be performed only for the historical turns, or the sample reconstruction may be performed for both the current turn and the historical turns. In some aspects, the last speaking turn of the original dialog sample is determined as the sample reconstruction turn matching the desired reconstruction turn when the desired reconstruction turn includes the current turn; and at least a portion of the historical speaking turns of the original dialog sample are determined as the sample reconstruction turns matching the desired reconstruction turn when the desired reconstruction turn includes the historical turns. The historical speaking turns are speaking turns before the last speaking turn.

For example, taking the original dialog sample 1 as an example, if the desired reconstruction turn is the historical turn, the sample reconstruction may be performed on at least a portion of the speaking turn 1 to the speaking turn 3. In this case, the reconstructed dialog sample matching the original dialog sample 1 may include a reconstructed dialog sample 1-3, which is obtained by performing the information transformation on all historical speaking turns. The reconstructed dialog sample matching the original dialog sample 1 may alternatively include a reconstructed dialog sample 1-4 and a reconstructed dialog sample 1-5, which are obtained by performing the information transformation on at least a portion of the historical speaking turns.

The reconstructed dialog sample 1-4 may be:
“(Speaking turn 1) speaker A: I ate a mango today.
(Speaking turn 2) speaker B: It is [really] very difficult to buy mangoes in this season.
(Speaking turn 3) speaker A: How about I give you a box? I have a lot.
(Speaking turn 4) speaker B: Great!”

The information transformation is performed on the reconstructed dialog sample 1-4 based on the original dialog sample 1 as follows: “a” in the speaking turn 1 is deleted; and “really” is added in the speaking turn 2.

The reconstructed dialog sample 1-5 may be:
“(Speaking turn 1) speaker A: I ate a mango today.
(Speaking turn 2) speaker B: It is very difficult to buy mangoes in this season.
(Speaking turn 3) speaker A: How about I give you a box? I have a lot.
(Speaking turn 4) speaker B: Great!”

The information transformation is performed on the reconstructed dialog sample 1-5 based on the original dialog sample 1 as follows: “a” in the speaking turn 1 is deleted.

In the foregoing embodiment, for an attack on the current turn, an attack region is the current speaking turn of the original sample. For an attack process of the historical turns, the attack region is at least a portion of the historical speaking turns, which can ensure that the sample reconstruction process matches characteristics of the dialog understanding model, thereby ensuring practicability of the robustness analysis result.

In an embodiment, the robustness analysis method for the dialog understanding model further includes: a desired reconstruction turn quantity in the sample reconstruction process is determined. In the present embodiment, the operation of determining at least a portion of the historical speaking turns of the original dialog sample as the sample reconstruction turns matching the desired reconstruction turn when the desired reconstruction turn includes the historical turns includes: the sample reconstruction turn matching the desired reconstruction turn is determined from the historical speaking turns of the original dialog sample according to the desired reconstruction turn quantity when the desired reconstruction turn includes the historical turns.

The desired reconstruction turn quantity is configured for representing a quantity of speaking turns in which the information transformation needs to be performed in the original dialog sample, namely, a quantity of sample reconstruction turns in the original dialog sample. In some aspects, when the desired reconstruction turn includes the historical turns, because the quantity of the historical speaking turns included in each original dialog sample is different, to further reduce the difference between different samples before and after reconstruction, a parameter, i.e., the desired reconstruction turn quantity may be introduced. The desired reconstruction turn quantity may be directly set by the developer according to the robustness analysis requirement, or may be determined by the server according to a reconstruction turn quantity condition set by the developer. The reconstruction turn quantity condition may refer to that the quantity of sample reconstruction turns in an original dialog sample is a set value, or may refer to that a ratio of the quantity of sample reconstruction turns in an original dialog sample to a total quantity of speaking turns is within a set range. This is not limited herein.

Further, the server may determine the sample reconstruction turn matching the desired reconstruction turn from the historical speaking turns of the original dialog sample according to the desired reconstruction turn quantity. For example, if the desired reconstruction turn quantity is 2, the server may select, for each original dialog sample, two historical speaking turns from the historical speaking turns in the original dialog sample as the sample reconstruction turns matching the desired reconstruction turn in the original dialog sample. In the practical application, the sample reconstruction turn may further be determined with reference to the turn information quantity, the turn sequence condition, and the like, to further reduce the difference between different samples before and after the reconstruction. For example, the sample reconstruction turn may be determined from the odd speaking turns of the historical speaking turns when the desired reconstruction turn quantity is satisfied; and for another example, the earlier historical speaking turn may be determined as the sample reconstruction turn when the desired reconstruction turn quantity is satisfied.

In the foregoing embodiment, when the desired reconstruction turn includes the historical turns, the sample reconstruction turn is determined with reference to the desired reconstruction turn quantity, whereby the difference between different samples before and after the reconstruction can be further reduced, and the accuracy of the robustness analysis result can be improved.

In an embodiment, the operation of performing sample reconstruction on each original dialog sample according to the sample reconstruction turn of each original dialog sample, to obtain an adversarial sample set matching the original sample set includes: to-be-reconstructed utterance information of each original dialog sample is determined according to the sample reconstruction turn of each original dialog sample; the information transformation is performed on each piece of the to-be-reconstructed utterance information, to obtain reconstructed utterance information matching the to-be-reconstructed utterance information; and the sample reconstruction is performed on each original dialog sample based on the reconstructed utterance information of each original dialog sample, to obtain the adversarial sample set matching the original sample set.

The to-be-reconstructed utterance information is utterance information of the sample reconstruction turn in the original dialog sample. In some aspects, if the semantics of a sample are significantly changed in the reconstruction process of the sample, an output result of the dialog understanding model may certainly be changed. If the robustness of the dialog understanding model is evaluated according to the change, a deviation of the robustness analysis result caused by impact of the semantic change may occur. Based on this, the server may determine the to-be-reconstructed utterance information of each original dialog sample according to the sample reconstruction turn of each original dialog sample. Then, the information transformation is performed on each piece of the to-be-reconstructed utterance information, to obtain the reconstructed utterance information matching the to-be-reconstructed utterance information. A semantic similarity between the mutually-matched to-be-reconstructed utterance information and reconstructed utterance information satisfies a similarity condition. The similarity condition, for example, may be that the semantic similarity is greater than a similarity threshold, or the semantic similarity is greater than or equal to the similarity threshold. Finally, the server performs the sample reconstruction on each original dialog sample based on the reconstructed utterance information of each original dialog sample, to obtain the adversarial sample set matching the original sample set.

In the present embodiment, the sample reconstruction is performed based on the reconstructed utterance information matching the to-be-reconstructed utterance information. Because the semantic similarity between the mutually-matched to-be-reconstructed utterance information and reconstructed utterance information satisfies the similarity condition, the semantic similarity between the original dialog sample and the reconstructed dialog sample can be maintained in the sample reconstruction process, thereby avoiding the impact of a sample semantic difference on the model evaluation data, and ensuring the accuracy of the robustness analysis result.

Further, the specific manner of performing sample reconstruction on each original dialog sample based on the reconstructed utterance information of each original dialog sample, to obtain the adversarial sample set matching the original sample set is not unique. For example, the server may extract original utterance information other than the to-be-reconstructed utterance information in the utterance information from the original dialog sample for each original dialog sample, and then combine the original utterance information and the reconstructed utterance information to obtain the adversarial dialog sample matching the original dialog sample, thereby determining the adversarial sample set including the adversarial dialog sample corresponding to each original dialog sample.

In an embodiment, the operation of performing sample reconstruction on each original dialog sample based on the reconstructed utterance information of each original dialog sample, to obtain the adversarial sample set matching the original sample set includes: for each original dialog sample, the to-be-reconstructed utterance information of the original dialog sample is replaced with reconstructed utterance information matching the to-be-reconstructed utterance information, to obtain the adversarial dialog sample matching the original dialog sample; and the adversarial sample set including the adversarial dialog sample corresponding to each original dialog sample is determined.

In some aspects, based on the original sample set, the server replaces the to-be-reconstructed utterance information of the original dialog sample with the reconstructed utterance information matching the to-be-reconstructed utterance information for each original dialog sample, to obtain the adversarial dialog sample matching the original dialog sample, thereby obtaining the adversarial sample set including the adversarial dialog sample corresponding to each original dialog sample. For example, the original dialog sample 1 is taken as an example. When the to-be-reconstructed utterance information is “great”, the server may perform the information transformation on the to-be-reconstructed utterance information, to obtain the reconstructed utterance information “wonderful” matching the to-be-reconstructed utterance information, and then replace “great” in the original dialog sample 1 with “wonderful”, to obtain the reconstructed dialog sample 1-2.

In the present embodiment, the sample reconstruction is implemented by replacing the utterance information, which is conducive to simplifying a sample reconstruction procedure and improving the operating efficiency of the robustness analysis process.

In an embodiment, the robustness analysis method for the dialog understanding model further includes: a desired reconstruction granularity in the sample reconstruction process is determined. In the present embodiment, the operation of performing the information transformation on each piece of the to-be-reconstructed utterance information, to obtain reconstructed utterance information matching the to-be-reconstructed utterance information includes: the information transformation is performed on each piece of the to-be-reconstructed utterance information in an information transformation manner matching the desired reconstruction granularity, to obtain reconstructed utterance information matching the to-be-reconstructed utterance information.

The desired reconstruction granularity is configured for representing an information transformation level in the information transformation process, and may include a granularity such as a character, a word, and a sentence. The information transformation manners corresponding to different levels of reconstruction granularity are different. For example, the information transformation manner of the character granularity may include algorithms such as TextBugger and TextFooler, and the information transformation manner of the word granularity may include a probabilistic weighted word significance (PWWS) algorithm and the like. Similar to the desired reconstruction turn and the desired reconstruction turn quantity, the desired reconstruction granularity may further be set directly by the developer according to the robustness analysis requirement, for example, set to the character granularity or the word granularity. Alternatively, the desired reconstruction granularity may be determined by the server according to a reconstruction granularity condition set by the developer. The reconstruction granularity condition, for example, may be that the reconstruction granularity is greater than the character granularity, or the reconstruction granularity is less than or equal to the word granularity.

In some aspects, the server may determine the desired reconstruction granularity in the sample reconstruction process, and perform the information transformation on each piece of the to-be-reconstructed utterance information according to the information transformation manner matching the desired reconstruction granularity, to obtain the reconstructed utterance information matching the to-be-reconstructed utterance information. In addition, for the same original dialog sample, when the quantity of sample reconstruction turns is multiple, the reconstruction granularity of the sample reconstruction turns may be the same or different. Taking an example in which the reconstruction granularity is less than or equal to the word granularity, the server may select a suitable reconstruction granularity from the character granularity and the word granularity for information transformation with reference to a semantic similarity principle for each sample reconstruction turn. For example, for the original dialog sample 1, the semantic similarity can be maintained after the word granularity transformation, and the word granularity may be employed as the reconstruction granularity for the information transformation. For the original dialog sample 2, the semantic similarity cannot be maintained after the word granularity transformation, and the character granularity may be employed as the reconstruction granularity for the information transformation.

In the present embodiment, the information transformation is performed on each piece of the to-be-reconstructed utterance information according to the information transformation manner matching the desired reconstruction granularity, to obtain the reconstructed utterance information matching the to-be-reconstructed utterance information, which can ensure a correlation between the reconstruction granularity in the reconstruction process of different original dialog samples, thereby further reducing the difference between different samples before and after the reconstruction, and improving the accuracy of the robustness analysis result.

In an embodiment, the operation of performing the information transformation on each piece of the to-be-reconstructed utterance information according to the information transformation manner matching the desired reconstruction granularity, to obtain the reconstructed utterance information matching the to-be-reconstructed utterance information includes: at least two candidate information transformation manners matching the desired reconstruction granularity are determined for each piece of the to-be-reconstructed utterance information; the information transformation is performed on the to-be-reconstructed utterance information based on each candidate information transformation manner, to obtain candidate reconstructed utterance information corresponding to each candidate information transformation manner; and the reconstructed utterance information whose semantic similarity to the to-be-reconstructed utterance information satisfies the similarity condition and whose semantic difference is maximum is determined from the candidate reconstructed utterance information.

In the practical application, in the robustness analysis process, it is desired that the semantic similarity can be maintained before and after the reconstruction of the sample, to ensure that the robustness analysis result is less interfered with by the semantic change; and furthermore, there is a need to ensure that the semantic difference of the reconstructed sample set with respect to the original sample set is sufficiently large to ensure that the analysis process can show the robustness in a worst case. Based on this, the server may determine at least two candidate information transformation manners matching the desired reconstruction granularity for each piece of the to-be-reconstructed utterance information. The information transformation is performed on the to-be-reconstructed utterance information based on each candidate information transformation manner, to obtain the candidate reconstructed utterance information corresponding to each candidate information transformation manner, and the semantic similarity between the candidate utterance information and the to-be-reconstructed utterance information is determined by means of semantic analysis. Finally, the reconstructed utterance information whose semantic similarity to the to-be-reconstructed utterance information satisfies the similarity condition and whose semantic difference is maximum is determined from the candidate reconstructed utterance information.

In the present embodiment, the reconstructed utterance information whose semantic similarity to the to-be-reconstructed utterance information satisfies the similarity condition and whose semantic difference is maximum is determined from the plurality of pieces of candidate reconstructed utterance information obtained in different information transformation manners, whereby a maximum perturbation is generated for the sample while maintaining the semantic similarity in the information transformation process, and the reliability of the robustness analysis result can be improved.

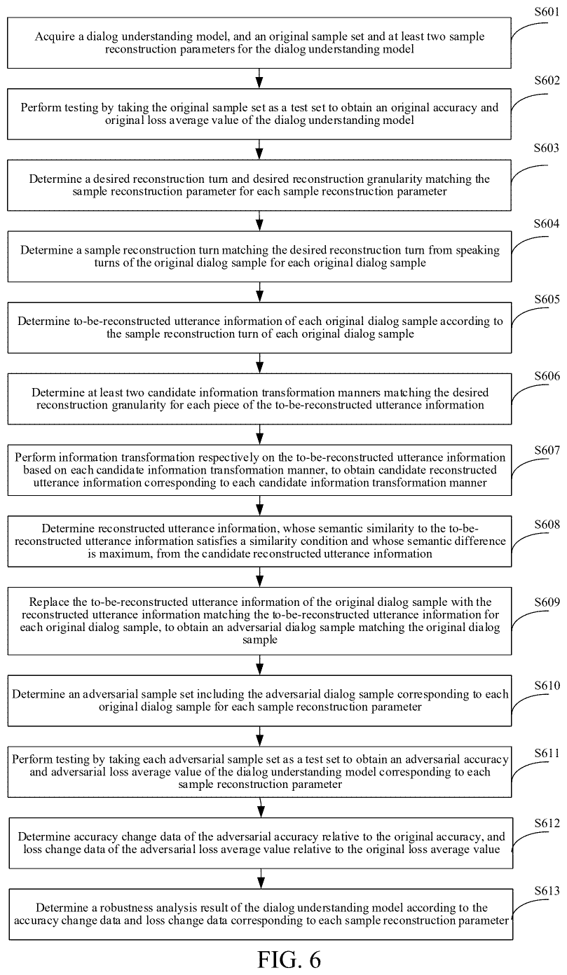

In an embodiment, as shown in FIG. 6, a robustness analysis method for a dialog understanding model is provided, the method may be performed by a computer device, the computer device may be the terminal or the server shown in FIG. 1, and in the present embodiment, taking the computer device being the server as an example, the method includes the following operations:

Operation S601: Acquire a dialog understanding model, and an original sample set and at least two sample reconstruction parameters for the dialog understanding model.

The original sample set includes a plurality of original dialog samples, and each round of dialog in each original dialog sample includes at least two speaking turns from different speakers. The sample reconstruction parameter may include a reconstruction turn parameter, a reconstruction granularity parameter, an information transformation manner, and the like. The reconstruction turn parameter is configured for representing a parameter condition that needs to be satisfied by the speaking turn in which information transformation needs to be performed in a reconstruction process. The reconstruction granularity parameter is configured for representing an information transformation level, and may include a granularity such as a character, a word, and a sentence. The information transformation manner may include deletion, replacement, addition, or the like. The replacement may be pronunciation-similar replacement, character-similar replacement, semantic-similar replacement, or the like.

Operation S602: Perform testing by taking the original sample set as a test set to obtain an original accuracy and an original loss average value of the dialog understanding model.

Operation S603: Determine a desired reconstruction turn and desired reconstruction granularity matching the sample reconstruction parameter for each sample reconstruction parameter.

The desired reconstruction turn may include a current turn and historical turns, and the desired reconstruction granularity may include a character granularity, a word granularity, and a sentence granularity.

Operation S604: Determine a sample reconstruction turn matching the desired reconstruction turn from the speaking turns of the original dialog sample for each original dialog sample.

Operation S605: Determine to-be-reconstructed utterance information of each original dialog sample according to the sample reconstruction turn of each original dialog sample.

Operation S606: Determine at least two candidate information transformation manners matching the desired reconstruction granularity for each piece of the to-be-reconstructed utterance information.

Operation S607: Perform information transformation on the to-be-reconstructed utterance information based on each candidate information transformation manner, to obtain candidate reconstructed utterance information corresponding to each candidate information transformation manner.

Operation S608: Determine the reconstructed utterance information, whose semantic similarity to the to-be-reconstructed utterance information satisfies a similarity condition and whose semantic difference is maximum, from the candidate reconstructed utterance information.

Operation S609: Replace, for each original dialog sample, the to-be-reconstructed utterance information of the original dialog sample with reconstructed utterance information matching the to-be-reconstructed utterance information, to obtain the adversarial dialog sample matching the original dialog sample.

Operation S610: Determine an adversarial sample set including an adversarial dialog sample corresponding to each original dialog sample for each sample reconstruction parameter.

Operation S611: Perform testing by taking each adversarial sample set as a test set to obtain an adversarial accuracy and an adversarial loss average value of each sample reconstruction parameter corresponding to the dialog understanding model.

Operation S612: Determine accuracy change data of the adversarial accuracy relative to the original accuracy, and loss change data of the adversarial loss average value relative to the original loss average value.

Operation S613: Determine a robustness analysis result of the dialog understanding model according to the respective accuracy change data and loss change data of each sample reconstruction parameter.

According to the foregoing robustness analysis method for the dialog understanding model, in the robustness analysis process of the dialog understanding model, based on the particular attribute that each original dialog sample includes a plurality of speaking turns, the information transformation is performed on the desired speaking turn based on the desired reconstruction granularity to reconstruct the original dialog sample, whereby the difference between different samples before and after the reconstruction can be reduced to a certain extent, the finally obtained robustness analysis result is more credible, and the accuracy of the robustness analysis result is improved. Moreover, the original sample set including a plurality of original dialog samples and the plurality of adversarial sample sets matching the original sample set are respectively taken as the test sets, and the robustness analysis result is determined according to the changes of the accuracy and loss average value of the dialog understanding model under different test sets, which is equivalent to combining the robustness of the model in multiple attack scenarios, whereby the accuracy of the robustness analysis result can further be improved.

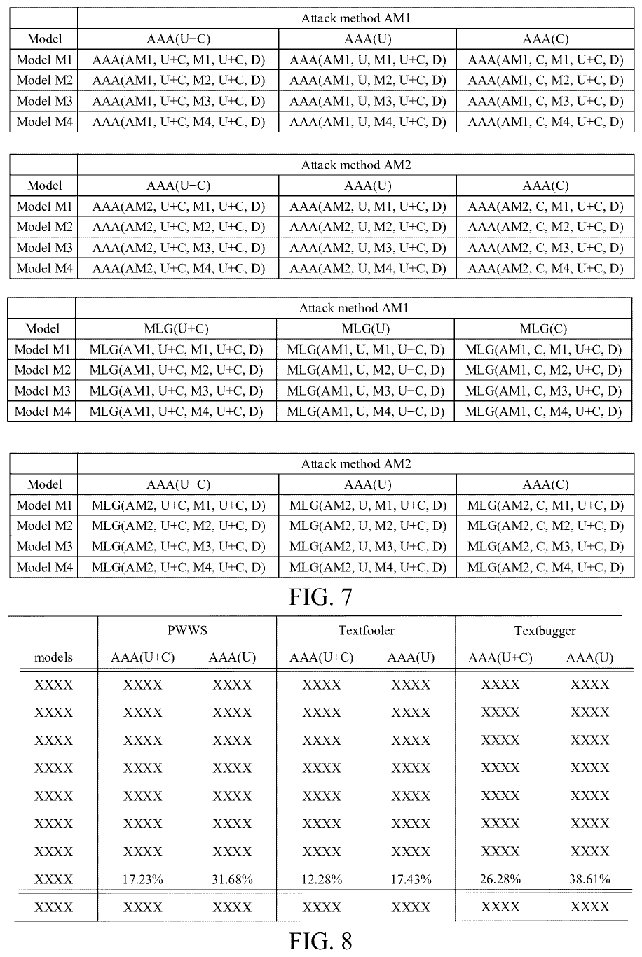

The robustness analysis method for the dialog understanding model in the present disclosure is described in detail below with reference to FIG. 7 to FIG. 9.

In some aspects, for the natural language processing tasks, after training on a training set, the model may well fit the training set, and may obtain a good effect on a test set. However, if correctness of a prediction result cannot be ensured when perturbation is added to a test set sample, it indicates that the robustness of the model is relatively poor. Therefore, the model robustness problem needs to be concerned about. In the dialog understanding task, there is no standard evaluation system for the robustness of the model. Based on this, the present disclosure provides an evaluation system, which performs robustness evaluation on the model from three perspectives of foregoing information, a current turn, and all dialogs. The foregoing information includes at least a portion of historical speaking turns of the dialog sample. At the same time, the present disclosure further provides two rules for evaluating the dialog robustness: Rule 1: Three indexes, namely, “AAA (C)”, “AAA (U)”, and “AAA (U+C)” are provided, which respectively reflect the robustness of the dialog understanding model for the “foregoing information”, “current round of dialog”, and “a complete dialog process”. Rule 2: Three indexes, namely, “MLG(C)”, “MLG(U)”, and “MLG(U+C)” are provided, which respectively reflect the robustness of the dialog understanding model for the “foregoing information”, “current round of dialog”, and “the complete dialog process” by calculating a value change degree of a loss function before and after an attack. “C” represents that a perturbation attack region (also referred to as perturbation attack scope) is the foregoing information, i.e., the historical turns, “U” represents that the perturbation attack region is the current turn, and “U+C” represents that the perturbation attack region includes the historical turns and the current turn; and “AAA” represents a model accuracy, and “MLG” represents a mean loss gradient.

A modeling formula of the robustness analysis process for the dialog understanding model is as follows:

$${min}_{θ} {\sum }_{( x , y ) ∼ D} [ {max}_{δ ∈ S} L ( θ , x + δ , y ) ]$$

where x represents an original dialog sample, including context information (represented by C below) of the historical turns and utterance information (represented by U below) of the current turn. y is a label carried by the original dialog sample x, i.e., a correct answer label. D represents an original sample set, and (x, y) is one of samples belonging to the original sample set D, δ is perturbation information, and a target of the robustness analysis is to maximize the loss function after the perturbation information δ is added to the sample x (to be specific, a small amount of perturbation causes a maximum difference between a prediction result probability and a correct answer). L is the loss function, which is configured for measuring the difference between the prediction result after the perturbation is added and the correct answer. θ is a dialog understanding model parameter, which is configured for reasoning a prediction probability outputted by the dialog understanding model after the perturbation δ is added to the sample x.

The loss function of the model before the perturbation information attack is:

$$L ( θ , x , y )$$

The loss function of the model after the attack (perturbation δ is added) is:

$$L ( θ , x + δ , y )$$

A definition of the loss function is as follows:

$$L ( θ , x , y ) = L ( Y , P ( Y \vert X ) ) = - log P ( Y \vert X )$$

A change of a loss function value before and after the attack (the perturbation δ is added) are as follows:

$$L ( θ , x + δ , y ) - L ( θ , x , y )$$

Based on the foregoing modeling manner, the evaluation system obtains two rules:

Rule 1: If the perturbation δ is added to the original dialog sample x to obtain the reconstructed dialog sample x+δ, causing a change in a result y outputted by the dialog understanding model, it indicates that the model does not defend against this attack, and the model is not robust in this attack.

Rule 2: The larger change value of the loss function value before and after the attack (the perturbation & is added) indicates less robustness of the dialog understanding model. Otherwise, the smaller change value of the loss function value indicates more robustness of the dialog understanding model.

Further, a context attack is a robustness test manner. Changes in loss function values before and after the attack are compared. The larger change indicates less robustness. Taking an example in which a dialog understanding task is emotion understanding, candidate emotion labels are happiness, sadness, and neutrality. For the foregoing original dialog sample 1, a probability of each candidate emotion label outputted by the model is: happiness 54%, neutrality 23%, and sadness 23%. Because a result of the maximum probability is “happiness”, the correct label “happiness” is hit.

For the reconstructed dialog sample 1-1 of the original dialog sample 1, the attack region is “U+C”, namely, both the current turn and the historical turns are attacked, and a probability of each candidate emotion label outputted by the model is: happiness 34%, neutrality 30%, and sadness 36%. Because the result of the maximum probability is “sadness”, the correct label is not hit.

For the reconstructed dialog sample 1-2 of the original dialog sample 1, the attack region is “U”, namely, only the current turn is attacked, and probability of each candidate emotion label outputted by the model is as follows: happiness 50%, neutrality 31%, and sadness 19%. Because the result of the maximum probability is “happiness”, the correct label is hit.

For the reconstructed dialog sample 1-3 of the original dialog sample 1, the attack region is “C”, namely, only the historical turns are attacked, and a probability of each candidate emotion label outputted by the model is as follows: happiness 30%, neutrality 44%, and sadness 26%. Because the result of the maximum probability is “neutrality”, the correct label is not hit.

Based on the foregoing Rule 1, an accuracy after attack (AAA) index of dialog understanding after the attack is proposed. Corresponding to the foregoing three attack regions, there are three calculation manners for the indexes:

$$AAA ( U + C ) = \frac{quantity of samples with correct prediction after simultaneous attack on U and C}{total quantity of test samples}$$

$$AAA ( U ) = \frac{quantity of samples with correct prediction after attack only on U}{total quantity of test samples}$$

$$AAA ( C ) = \frac{quantity of samples with correct prediction after attack only on C}{total quantity of test samples}$$

AAA (U+C) refers to the accuracy of the dialog understanding model under the test of the adversarial sample set where the attack region includes the current turn and the historical turns. The reconstructed dialog sample 1-1 shows a result of a sample after the U+C attack, and a prediction result of the sample after the attack is incorrect, whereby a quantity of samples with correct prediction is 0. A value of AAA (U+C) is in a range of [0, 1]. A larger value of AAA (U+C) indicates that the evaluated dialog understanding model is more robust (has a strong anti-attack capability) to the attack on the foregoing information and the current turn, namely, the understanding for a whole dialog process shows strong robustness.

AAA (U) refers to the accuracy of the dialog understanding model under the test of the adversarial sample set where the attack region only includes the current turn. The reconstructed dialog sample 1-2 shows a result of a sample after the U attack, and the prediction result of the sample after the attack is correct, whereby the quantity of samples with correct prediction is 1. Similarly, the value of AAA (U) is in a range of [0, 1]. A larger value of AAA (U) indicates that the evaluated dialog understanding model is more robust (has a strong anti-attack capability) to the attack on the current turn, namely, the understanding in the current round of dialog shows strong robustness.

AAA (C) refers to the accuracy of the dialog understanding model under the test of the adversarial sample set where the attack region only includes the historical turns. The reconstructed dialog sample 1-3 shows a result of a sample after the C attack, and the prediction result of the sample after the attack is incorrect, whereby the quantity of samples with correct prediction is 0. Similarly, a value of AAA (C) is in a range of [0, 1]. A larger value of AAA (C) indicates that the evaluated dialog understanding model is more robust (has strong anti-attack capability) to the attack on the historical turns, namely, the understanding in the foregoing information of the dialog shows strong robustness.

In addition, in the present embodiment, the original accuracy of the dialog understanding model in the original dialog sample set is 1 by default. Therefore, the foregoing AAA index may reflect an accuracy change of the dialog understanding model before and after the attack.

Based on the foregoing Rule 2, a mean loss gradient (MLG) before and after the attack is proposed to evaluate the robustness of the dialog understanding model, and there are three calculation manners:

$$MLG ( U + C ) = \frac{{\sum }_{1}^{N} [ L ( θ , x + {δ}_{U + C} , y ) - L ( θ , x , y ) ]}{n}$$

$$MLG ( U ) = \frac{{\sum }_{1}^{n} [ L ( θ , x + {δ}_{U} , y ) - L ( θ , x , y ) ]}{n}$$

$$MLG ( C ) = \frac{{\sum }_{1}^{n} [ L ( θ , x + {δ}_{C} , y ) - L ( θ , x , y ) ]}{n}$$

where MLG(U+C) refers to the mean loss gradient of the dialog understanding model under the test of the adversarial sample set where the attack region includes the current turn and the historical turns. n is a total quantity of test samples. The larger result of MLG(U+C) indicates a larger change in the understanding of the model after the attack, and less robustness of the model understanding in the whole dialog process. On the contrary, a smaller result of MLG(U+C) indicates a smaller change in the understanding of the model after the attack, and more robustness of the model understanding in the whole dialog process. Taking the reconstructed dialog sample 1-1 as an example, the sample undergoes the U+C attack, and a loss value after the attack is: L(θ,x+8,y)=−log P(y=happy|x+δ)=|log 0.34.

The loss value before the attack is: L(θ,x,y)=−log P(y=happy|x)=−log 0.54.

Then, the mean loss gradient is: MLG(U+C)=L(θ,x+d,y)−L(θ,x,y)=−log 0.34−(−log 0.54)=0.2009.

MLG(U) refers to the mean loss gradient of the dialog understanding model under the test of the adversarial sample set where the attack region only includes the current turn. n is a total quantity of test samples. A larger result of MLG(U) indicates a larger change in model understanding after the attack, and less robustness of the model understanding in the current turn. On the contrary, a smaller result of MLG(U) indicates a smaller change in the model understanding after the attack, and more robustness of the model understanding in the current turn. Taking the reconstructed dialog sample 1-2 as an example, the sample undergoes the U attack, and the loss value after the attack is: L(θ,x+d,y)=log P(y=happy|x+δ)=−log 0.5.

The loss value before the attack is −log 0.54. Then, the mean loss gradient is:

$$MLG ( C ) = L ( θ , x + δ , y ) - L ( θ , x , y ) = - log 0.3 - ( - log 0.54 ) = 0.2552 .$$

MLG(C) refers to the mean loss gradient of the dialog understanding model under the test of the adversarial sample set where the attack region only includes the historical turns. n is a total quantity of test samples. A larger result of MLG(C) indicates a larger change in the model understanding after the attack, and less robustness of the model understanding in the historical turns. On the contrary, the smaller result of MLG(C) A indicates a smaller change in the model understanding after the attack, and more robustness of the model understanding in the current turn. Taking the reconstructed dialog sample 1-3 as an example, the sample undergoes the C attack, and the loss value after the attack is: L(θ,x+d,y)=−log P(y=happy|x+δ)=−log 0.3.

The loss value before the attack is −log 0.54. Then, the mean loss gradient is:

$$MLG ( U ) = L ( θ , x + δ , y ) - L ( θ , x , y ) = - log 0.5 - ( - log 0.54 ) = 0.0334 .$$

By means of the test with the above reconstructed samples (one sample, n=1), MLG(U)<MLG(U+C)<MLG(C), the dialog robustness result reflected by the evaluated dialog understanding model on the sample is as follows: the robustness in the current turn (U) is relatively good, and the performance in the historical turns (C) is the least robust. However, due to the interference on all dialog information, the performance is less robust.

FIG. 7 shows a robustness index system of the dialog understanding model provided by the present disclosure. In a specified data set D, robustness analysis results of four models (M1-M4) in two attack methods (AM1 and AM2) are evaluated. An index AAA Score (an attack method, a dialog understanding model, and an attack region) corresponds to the robustness results of three indexes of each model in the attack methods (AM1 to AM2). A value of AAA Score is in a range of [0, 1]. For example, AAA (AM1, U+C, M1, U+C, D) represents an accuracy of the model M1 when a data set D is the original sample set, an attack region is U+C, and an attack algorithm is AM1. Further, for the attack method, different attack algorithms under different levels of granularity (character granularity/word granularity/sentence granularity) may be selected. For example, the attack algorithm of the character granularity includes TextBugger/TextFooler, and the attack algorithm of the word granularity includes PWWS, which may be all employed as actual attack methods (AM). The dialog understanding model, i.e., an evaluated dialog understanding model, may include four to-be-evaluated models M1-M4. The attack region is a region for evaluating the robustness, and may include a current turn, historical turns, and a complete dialog (namely, including the current turn and the historical turns). To be specific, U corresponds to a calculation formula AAA (U)/MLG(U), evaluating the robustness of the model for the current turn. C corresponds to a calculation formula AAA (C)/MLG(C), evaluating the robustness of the model for the foregoing information. U+C corresponds to AAA (U+)/MLG(U+C), namely, evaluating the robustness of the model for the inputted information of the complete dialog. According to an array formed by the indexes in FIG. 7, the robustness of the model may be comprehensively evaluated and determined from three perspectives: the current turn (U)/foregoing information (U)/complete dialog (U+C).

In the practical application, some of the indexes may be selected for target evaluation on the robustness of the dialog understanding model. For example, as shown in FIG. 8, an example in which the robustness of different dialog understanding models is evaluated is taken for the targeted evaluation on the robustness of the dialog understanding model in the current turn (U) and the complete dialog (U+C) of the dialog. In a specific experiment, three different attack methods (AM1 to AM3) are employed, and respectively correspond to the attack algorithms: PWWS, TextFooler, and TextBugger. In the three attack methods, the robustness evaluation is performed by employing the evaluation index AAA (U+C)/AAA (U) provided by the present disclosure, to evaluate an anti-interference capability (i.e., the robustness) of the current turn (U) of different dialog understanding models and the anti-interference capability (i.e., the robustness) of the complete dialog (U+C).

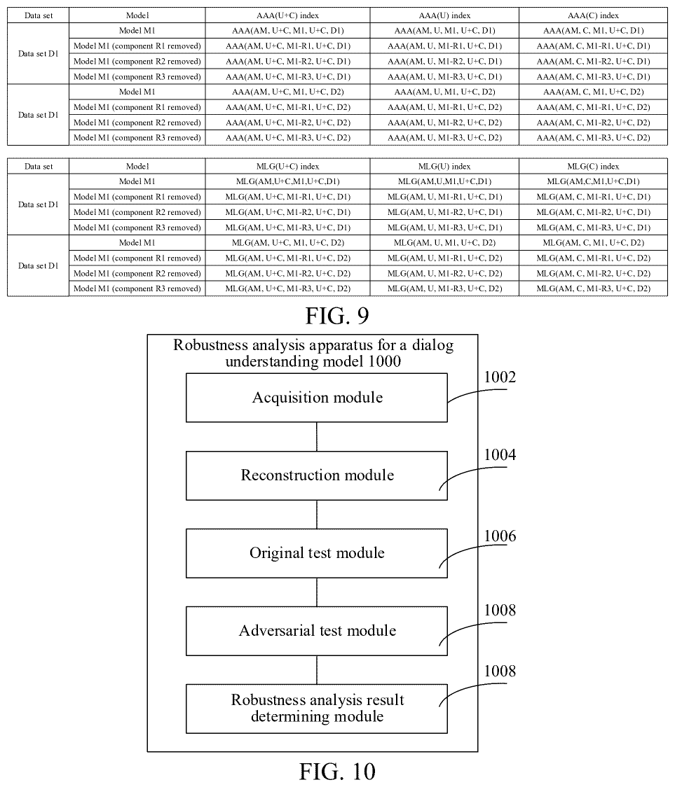

In an ablation experiment scenario, an impact of different components in the dialog understanding model on the robustness result needs to be analyzed. FIG. 9 shows a specific method of applying a robustness index evaluation system provided by the present disclosure to an ablation experiment. In an experiment, an impact of addition or deletion of different components (R1-R3) in the evaluated model M1 on the final robustness result is validated by employing multiple data sets (D1-D2). The impact includes a positive impact, a negative impact, and an impact degree, which may be comprehensively evaluated and validated by employing the AAA (U+C)/AAA (U)/AAA (C) and MLG(U+C)/MLG(U)/MLG(C) index systems.

Although the operations are displayed sequentially according to instructions of arrows in the flowcharts involved in various foregoing embodiments, these operations are not necessarily performed sequentially according to the sequence instructed by the arrows. Unless otherwise explicitly specified in the present disclosure, execution of the operations is not strictly limited, and the operations may be performed in other sequences. Moreover, at least some of the operations in the flowcharts involved in various foregoing embodiments may include a plurality of operations or a plurality of stages. The operations or stages are not necessarily performed at the same moment but may be performed at different moments. The operations or stages are not necessarily sequentially performed, but may be performed alternately with other operations or at least some operations or stages of other operations.

Based on a same invention concept, an embodiment of the present disclosure further provides a robustness analysis apparatus configured to implement the foregoing robustness analysis method for the dialog understanding model. An implementation for resolving problems provided in the apparatus is similar to the implementation described in the foregoing method. Therefore, for specific limitations to the following one or more embodiments of the robustness analysis model for one or more dialog understanding models provided below, refer to the foregoing limitations to the robustness analysis method for the dialog understanding model. Details are not described herein again.

In an embodiment, as shown in FIG. 10, a robustness analysis apparatus 1000 for a dialog understanding model is provided, which includes: an acquisition module 1002, a reconstruction module 1004, an original test module 1006, an adversarial test module 1008, and a robustness analysis result determining module 1010, where
the acquisition module 1002 is configured to acquire an original sample set; the original sample set includes a plurality of original dialog samples; each round of dialog in each original dialog sample includes at least two speaking turns from different speakers;
the reconstruction module 1004 is configured to separately reconstruct each original dialog sample for at least a portion of the speaking turns, to obtain an adversarial sample set matching the original sample set;
the original test module 1006 is configured to perform testing by taking the original sample set as a test set to obtain original evaluation data of the dialog understanding model;
the adversarial test module 1008 is configured to perform testing by taking the adversarial sample set as a test set to obtain adversarial evaluation data of the dialog understanding model; and
the robustness analysis result determining module 1010 is configured to determine a robustness analysis result of the dialog understanding model according to a change of the adversarial evaluation data relative to the original evaluation data.

In an embodiment, the reconstruction module 1004 includes: a desired reconstruction turn determining submodule, configured to determine a desired reconstruction turn in a sample reconstruction process; a sample reconstruction turn determining submodule, configured to determine a sample reconstruction turn matching the desired reconstruction turn from the speaking turns of the original dialog sample for each original dialog sample; and a reconstruction submodule, configured to perform sample reconstruction on each original dialog sample according to the sample reconstruction turn of each original dialog sample, to obtain the adversarial sample set matching the original sample set.

In an embodiment, the sample reconstruction turn determining submodule is configured to: determine a last speaking turn of the original dialog sample as the sample reconstruction turn matching the desired reconstruction turn when the desired reconstruction turn includes a current turn; and determine at least a portion of the historical speaking turns of the original dialog sample as the sample reconstruction turns matching the desired reconstruction turn when the desired reconstruction turn includes the historical turns, where the historical speaking turns are speaking turns before the last speaking turn.

In an embodiment, the robustness analysis apparatus for the dialog understanding model further includes: a desired reconstruction turn quantity determining module, configured to determine a desired reconstruction turn quantity in the sample reconstruction process. In the present embodiment, the sample reconstruction turn determining submodule is further configured to: determine the sample reconstruction turn matching the desired reconstruction turn from the historical speaking turns of the original dialog sample according to the desired reconstruction turn quantity when the desired reconstruction turn includes the historical turns.

In an embodiment, the reconstruction submodule includes: a to-be-reconstructed utterance information determining unit, configured to determine to-be-reconstructed utterance information of each original dialog sample according to the sample reconstruction turn of each original dialog sample; an information transformation unit, configured to perform information transformation on each piece of the to-be-reconstructed utterance information, to obtain reconstructed utterance information matching the to-be-reconstructed utterance information; and a reconstruction unit, configured to perform sample reconstruction on each original dialog sample based on the reconstructed utterance information of each original dialog sample, to obtain the adversarial sample set matching the original sample set. A semantic similarity between the mutually-matched to-be-reconstructed utterance information and reconstructed utterance information satisfies a similarity condition.

In an embodiment, the robustness analysis apparatus for the dialog understanding model further includes: a desired reconstruction granularity determining module, configured to determine a desired reconstruction granularity in the sample reconstruction process. In the present embodiment, the information transformation unit is configured to: perform the information transformation on each piece of the to-be-reconstructed utterance information in an information transformation manner matching the desired reconstruction granularity, to obtain the reconstructed utterance information matching the to-be-reconstructed utterance information.

In an embodiment, the information transformation unit is configured to: determine at least two candidate information transformation manners matching the desired reconstruction granularity for each piece of the to-be-reconstructed utterance information; perform the information transformation on the to-be-reconstructed utterance information based on each candidate information transformation manner, to obtain candidate reconstructed utterance information corresponding to each candidate information transformation manner; and determine the reconstructed utterance information, whose semantic similarity to the to-be-reconstructed utterance information satisfies the similarity condition and whose semantic difference is maximum, from the candidate reconstructed utterance information.

In an embodiment, the reconstruction unit is configured to: replace the to-be-reconstructed utterance information of the original dialog sample with the reconstructed utterance information matching the to-be-reconstructed utterance information for each original dialog sample, to obtain the adversarial dialog sample matching the original dialog sample; and determine the adversarial sample set including the adversarial dialog sample corresponding to each original dialog sample.

In an embodiment, the original evaluation data includes an original accuracy, and the adversarial evaluation data includes an adversarial accuracy. In the present embodiment, the robustness analysis result determining module 1010 is configured to: determine accuracy change data of the adversarial accuracy relative to the original accuracy; and determine the robustness analysis result of the dialog understanding model based on the accuracy change data.

In an embodiment, the original evaluation data includes an original loss statistical value, and the adversarial evaluation data includes an adversarial loss statistical value. In the present embodiment, the robustness analysis result determining module 1010 is configured to: determine loss change data of the adversarial loss statistical value relative to the original loss statistical value; and determine the robustness analysis result of the dialog understanding model based on the loss change data.

In an embodiment, a quantity of the adversarial sample sets is at least two. In the present embodiment, the adversarial test module 1008 is configured to: perform testing by taking each adversarial sample set as a test set to obtain adversarial evaluation data of the dialog understanding model corresponding to each adversarial sample set. The robustness analysis result determining module 1010 is configured to: determine the robustness analysis result of the dialog understanding model according to a change of each piece of adversarial evaluation data relative to the original evaluation data.

All or a part of the modules in the foregoing robustness analysis apparatus for the dialog understanding model may be implemented by using software, hardware, or a combination thereof. The foregoing modules may be embedded in or may be independent from a processor in a computer device in a hardware form, or may be stored in a memory in the computer device in a software form, to facilitate the processor to perform the operations corresponding to each module.

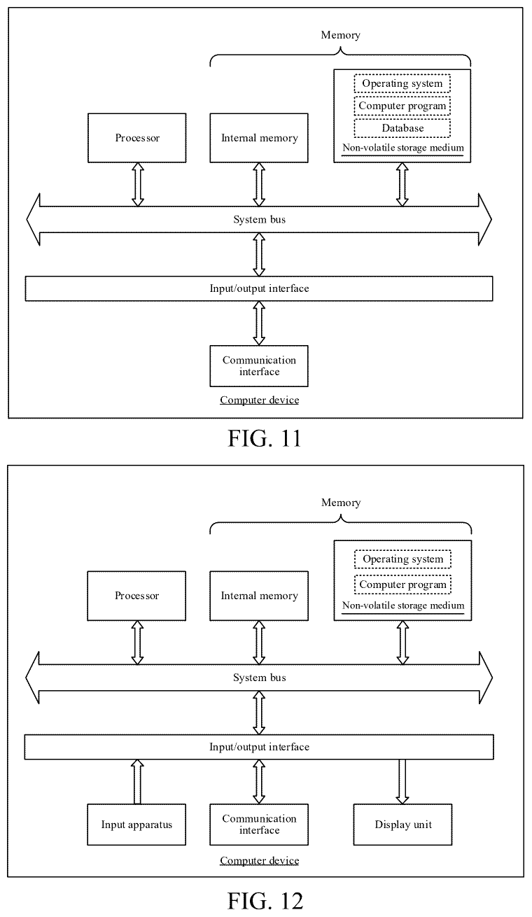

In an embodiment, provided is a computer device. The computer device may be a server or a terminal, and an internal structure diagram of the computer device may be shown in FIG. 11. The computer device includes one or more processors, a memory, an input/output (I/O) interface, and a communication interface. The processor, the memory, and the input/output interface are connected to each other by using a system bus, and the communication interface is connected to the system bus by using the input/output interface. The processor of the computer device is configured to provide computing and control capabilities. The memory of the computer device includes a non-volatile storage medium and an internal memory. The non-volatile storage medium stores an operating system, computer-readable instructions, and a database. The internal memory provides an environment for running the operating system and the computer-readable instructions in the non-volatile storage medium. The database of the computer device is configured to store data that needs to be used or generated in a robustness analysis process of the dialog understanding model, such as an original sample set, an adversarial sample set, original evaluation data, adversarial evaluation data, and a robustness analysis result. The input/output interface of the computer device is configured to exchange information between the processor and peripheral equipment. The communication interface of the computer device is configured to connect and communicate with an external terminal over a network. The computer-readable instructions, when executed by the processor, implement a robustness analysis method for a dialog understanding model.

In an embodiment, provided is a computer device. The computer device may be a terminal, and an internal structure diagram of the computer device may be shown in FIG. 12. The computer device includes one or more processors, a memory, an input/output interface, a communication interface, a display unit, and an input apparatus. The processor, the memory, and the input/output interface are connected by a system bus, and the communication interface, the display unit, and the input apparatus are connected to the system bus through the input/output interface. The processor of the computer device is configured to provide computing and control capabilities. The memory of the computer device includes a non-volatile storage medium and an internal memory. The non-volatile storage medium stores an operating system and computer-readable instructions. The internal memory provides an environment for running the operating system and the computer-readable instructions in the non-volatile storage medium. The input/output interface of the computer device is configured to exchange information between the processor and peripheral equipment. The communication interface of the computer device is configured to communicate with external terminals in a wired way or a wireless way, and the wireless way may be implemented by WIFI, mobile cellular networks, near-field communication (NFC) or other technologies. The computer-readable instructions, when executed by the processor, implement a robustness analysis method for a dialog understanding model. The display unit of the computer device may be configured for forming a visually visible screen and may be a display screen, a projection apparatus, or a virtual reality imaging apparatus. The display screen may be a liquid crystal display screen or an e-ink display screen. The input apparatus of the computer device may be a touch layer covering the display screen, or may be a button, a trackball, or a touchpad disposed on a housing of the computer device, or may be an external keyboard, touchpad, a mouse or the like.

A person skilled in the art may understand that the structures shown in FIG. 11 or FIG. 12 are merely block diagrams of some structures related to solutions of the present disclosure, and may not constitute limitations to the computer device to which the solutions of the present disclosure is applied. A specific computer device may include more or fewer components than those shown in the figure, or some components may be combined, or a different component deployment may be used.

In one embodiment, provided is a computer device. The computer device includes a memory and one or more processors. The memory has computer-readable instructions stored therein. The one or more processors, when executing the computer-readable instructions, implement the operations in the foregoing method embodiments.

In one embodiment, provided is a computer-readable storage medium. The computer-readable storage medium has computer-readable instructions stored therein. The computer-readable instructions, when executed by one or more processors, implement the operations in the foregoing method embodiments.

In one embodiment, provided is a computer program product, including computer-readable instructions. The computer-readable instructions, when executed by one or more processors, implement the operations in the foregoing method embodiments.

In addition, the user information (including but not limited to information of user equipment, personal information of the user), and data (including but not limited to to-be-analyzed data, stored data, and to-be-displayed data) involved in this disclosure are all authorized by the user or fully authorized by all parties, and the collection, use and processing of relevant data need to comply with relevant laws, regulations and standards of relevant territories and regions. In addition, the user may choose not to perform authorization on the user information and related data, or may refuse or conveniently refuse to push information, or the like.

A person of ordinary skill in the art may understand that all or some of procedures of the method in the foregoing embodiments may be implemented by computer-readable instructions instructing relevant hardware. The computer-readable instructions may be stored in a non-volatile computer-readable storage medium. The computer-readable instructions, when executed, may include the procedures of each foregoing method embodiment. Any reference to a memory, a database, or another medium used in the embodiments provided in this disclosure may include at least one of a non-volatile memory and a volatile memory. The non-volatile memory may include a read-only memory (ROM), a magnetic tape, a floppy disk, a flash memory, an optical memory, a high-density embedded non-volatile memory, a resistive random access memory (ReRAM), a magnetoresistive random access memory (MRAM), a ferroelectric random access memory (FRAM), a phase change memory (PCM), a graphene memory, or the like. The volatile memory may include a random-access memory (RAM) and an external cache. As illustration rather than limitation, the RAM may be in various forms, such as a static random access memory (SRAM), or a dynamic random access memory (DRAM). The database involved in the embodiments provided in this disclosure may include at least one of a relational database and a non-relational database. The non-relational database may include a blockchain-based distributed database, or the like, but is not limited thereto. The processor involved in the embodiments provided in this disclosure may be a general-purpose processor, a central processing unit, a graphics processing unit, a digital signal processor, a programmable logic device, a quantum computing-based data processing logic device, or the like, but is not limited thereto.

One or more modules, submodules, and/or units of the apparatus can be implemented by processing circuitry, software, or a combination thereof, for example. The term module (and other similar terms such as unit, submodule, etc.) in this disclosure may refer to a software module, a hardware module, or a combination thereof. A software module (e.g., computer program) may be developed using a computer programming language and stored in memory or non-transitory computer-readable medium. The software module stored in the memory or medium is executable by a processor to thereby cause the processor to perform the operations of the module. A hardware module may be implemented using processing circuitry, including at least one processor and/or memory. Each hardware module can be implemented using one or more processors (or processors and memory). Likewise, a processor (or processors and memory) can be used to implement one or more hardware modules. Moreover, each module can be part of an overall module that includes the functionalities of the module. Modules can be combined, integrated, separated, and/or duplicated to support various applications. Also, a function being performed at a particular module can be performed at one or more other modules and/or by one or more other devices instead of or in addition to the function performed at the particular module. Further, modules can be implemented across multiple devices and/or other components local or remote to one another. Additionally, modules can be moved from one device and added to another device, and/or can be included in both devices.

The use of “at least one of” or “one of” in the disclosure is intended to include any one or a combination of the recited elements. For example, references to at least one of A, B, or C; at least one of A, B, and C; at least one of A, B, and/or C; and at least one of A to C are intended to include only A, only B, only C or any combination thereof. References to one of A or B and one of A and B are intended to include A or B or (A and B). The use of “one of” does not preclude any combination of the recited elements when applicable, such as when the elements are not mutually exclusive.

Technical features of the foregoing embodiments may be combined. To make description concise, not all combinations of the technical features in the foregoing embodiments are described. However, the combinations of these technical features shall be considered as falling within the scope of the present disclosure.

The foregoing disclosure includes some embodiments of this disclosure which are not intended to limit the scope of this disclosure. Other embodiments shall also fall within the scope of this disclosure.

What is claimed is:

1. A method of robustness analysis for a dialog understanding model, comprising:
acquiring an original sample set, the original sample set comprising a plurality of original dialog samples, and each original dialog sample in the plurality of original dialog samples comprising a round of dialog having at least two speaking turns from different speakers;
reconstructing the plurality of original dialog samples to obtain at least an adversarial sample set associated with a perturbation attack scope, each original dialog sample in the plurality of original dialog samples being modified according to the perturbation attack scope to reconstruct a modified dialog sample in the adversarial sample set, the perturbation attack scope including at least one of a current turn scope and a historical turn scope in the at least two speaking turns;
performing a first test of the dialog understanding model by using the original sample set to obtain original evaluation data of the dialog understanding model;
performing a second test of the dialog understanding model by using the adversarial sample set to obtain adversarial evaluation data of the dialog understanding model; and
determining a robustness analysis result of the dialog understanding model according to a change of the adversarial evaluation data with respect to the original evaluation data.

2. The method according to claim 1, wherein the reconstructing comprises:
determining one or more desired reconstruction turns for the perturbation attack scope;
determining, for an original dialog sample having a plurality of speaking turns, one or more sample reconstruction turns from the plurality of speaking turns according to the one or more desired reconstruction turns; and
performing sample reconstruction on the original dialog sample according to the one or more sample reconstruction turns, to obtain a modified dialog sample for the original dialog sample.

3. The method according to claim 2, wherein the determining the one or more sample reconstruction turns comprises:
determining a last speaking turn of the original dialog sample as one of the one or more sample reconstruction turns when the perturbation attack scope includes the current turn scope; and
determining at least a historical speaking turn of the original dialog sample as one of the one or more sample reconstruction turns when the perturbation attack scope comprises the historical turn scope, the historical speaking turn being a speaking turn before the last speaking turn in the original dialog sample.

4. The method according to claim 3, further comprising:
determining a desired reconstruction turn quantity of the one or more desired reconstruction turns, wherein:
the determining at least the historical speaking turn comprises:
determining a portion of historical speaking turns of the original dialog sample according to the desired reconstruction turn quantity.

5. The method according to claim 2, wherein the performing the sample reconstruction comprises:
determining at least a piece of to-be-reconstructed utterance information of the original dialog sample according to the one or more sample reconstruction turns; and
performing information transformation on at least the piece of to-be-reconstructed utterance information, to obtain at least a piece of reconstructed utterance information, the piece of to-be-reconstructed utterance information and the piece of reconstructed utterance information satisfying a semantic similarity condition.

6. The method according to claim 5, further comprising:
determining a desired reconstruction granularity, wherein:
the performing the information transformation comprises:
performing the information transformation according to the desired reconstruction granularity.

7. The method according to claim 6, wherein the performing the information transformation according to the desired reconstruction granularity comprises:
determining at least a first candidate information transformation manner and a second candidate information transformation manner according to the desired reconstruction granularity;
performing information transformation on the piece of to-be-reconstructed utterance information respectively according to at least the first candidate information transformation manner and the second candidate information transformation manner to obtain at least a first piece of candidate reconstructed utterance information and a second piece of candidate reconstructed utterance information; and
determining the piece of reconstructed utterance information according to a selected candidate from at least the first piece of candidate reconstructed utterance information and the second piece of candidate reconstructed utterance information, the selected candidate satisfying a semantic similarity condition with the piece of to-be-reconstructed utterance information and having a maximum semantic difference to the piece of to-be-reconstructed utterance information.

8. The method according to claim 5, wherein the performing the sample reconstruction comprises:
replacing the piece of to-be-reconstructed utterance information in the original dialog sample with the piece of reconstructed utterance information, to obtain the modified dialog sample for the original dialog sample.

9. The method according to claim 1, wherein:
the original evaluation data comprises an original accuracy, and the adversarial evaluation data comprises an adversarial accuracy; and
the determining the robustness analysis result comprises:
determining accuracy change data of the adversarial accuracy with respect to the original accuracy; and
determining the robustness analysis result of the dialog understanding model based on the accuracy change data.

10. The method according to claim 1, wherein:
the original evaluation data comprises an original loss statistical value, and the adversarial evaluation data comprises an adversarial loss statistical value; and
the determining the robustness analysis result comprises:
determining loss change data of the adversarial loss statistical value with respect to the original loss statistical value; and
determining the robustness analysis result of the dialog understanding model based on the loss change data.

11. The method according to claim 1, wherein:
at least the adversarial sample set include at least a first adversarial sample set and a second adversarial sample set;
the performing the second test comprises:
performing the second test respectively based on at least the first adversarial sample set and the second adversarial sample set to obtain at least a first adversarial evaluation data of the dialog understanding model for the first adversarial sample set, and a second adversarial evaluation data of the dialog understanding model for the first adversarial sample set; and
the determining the robustness analysis result comprises:
determining the robustness analysis result of the dialog understanding model according to respective changes of at least the first adversarial evaluation data and the second adversarial evaluation data with respect to the original evaluation data.

12. An apparatus of robustness analysis for a dialog understanding model, comprising processing circuitry configured to:
acquire an original sample set, the original sample set comprising a plurality of original dialog samples, and each original dialog sample in the plurality of original dialog samples comprising a round of dialog having at least two speaking turns from different speakers;
reconstruct the plurality of original dialog samples to obtain at least an adversarial sample set associated with a perturbation attack scope, each original dialog sample in the plurality of original dialog samples being modified according to the perturbation attack scope to reconstruct a modified dialog sample in the adversarial sample set, the perturbation attack scope including at least one of a current turn scope and a historical turn scope in the at least two speaking turns;
perform a first test of the dialog understanding model by using the original sample set to obtain original evaluation data of the dialog understanding model;
perform a second test of the dialog understanding model by using the adversarial sample set to obtain adversarial evaluation data of the dialog understanding model; and
determine a robustness analysis result of the dialog understanding model according to a change of the adversarial evaluation data with respect to the original evaluation data.

13. The apparatus according to claim 12, wherein the processing circuitry is configured to:
determine one or more desired reconstruction turns for the perturbation attack scope;
determine, for an original dialog sample having a plurality of speaking turns, one or more sample reconstruction turns from the plurality of speaking turns according to the one or more desired reconstruction turns; and
perform sample reconstruction on the original dialog sample according to the one or more sample reconstruction turns, to obtain a modified dialog sample for the original dialog sample.

14. The apparatus according to claim 13, wherein the processing circuitry is configured to:
determine a last speaking turn of the original dialog sample as one of the one or more sample reconstruction turns when the perturbation attack scope includes the current turn scope; and
determine at least a historical speaking turn of the original dialog sample as one of the one or more sample reconstruction turns when the perturbation attack scope comprises the historical turn scope, the historical speaking turn being a speaking turn before the last speaking turn in the original dialog sample.

15. The apparatus according to claim 14, wherein the processing circuitry is configured to:
determine a desired reconstruction turn quantity of the one or more desired reconstruction turns; and
determine a portion of historical speaking turns of the original dialog sample according to the desired reconstruction turn quantity.

16. The apparatus according to claim 13, wherein the processing circuitry is configured to:
determine at least a piece of to-be-reconstructed utterance information of the original dialog sample according to the one or more sample reconstruction turns; and
perform information transformation on at least the piece of to-be-reconstructed utterance information, to obtain at least a piece of reconstructed utterance information, the piece of to-be-reconstructed utterance information and the piece of reconstructed utterance information satisfying a semantic similarity condition.

17. The apparatus according to claim 16, wherein the processing circuitry is configured to:
determine a desired reconstruction granularity; and
perform the information transformation according to the desired reconstruction granularity.

18. The apparatus according to claim 17, wherein the processing circuitry is configured to:
determine at least a first candidate information transformation manner and a second candidate information transformation manner according to the desired reconstruction granularity;
perform information transformation on the piece of to-be-reconstructed utterance information respectively according to at least the first candidate information transformation manner and the second candidate information transformation manner to obtain at least a first piece of candidate reconstructed utterance information and a second piece of candidate reconstructed utterance information; and
determine the piece of reconstructed utterance information according to a selected candidate from at least the first piece of candidate reconstructed utterance information and the second piece of candidate reconstructed utterance information, the selected candidate satisfying a semantic similarity condition with the piece of to-be-reconstructed utterance information and having a maximum semantic difference to the piece of to-be-reconstructed utterance information.

19. The apparatus according to claim 16, wherein the processing circuitry is configured to:
replacing at least the piece of to-be-reconstructed utterance information in the original dialog sample with the piece of reconstructed utterance information, to obtain the modified dialog sample for the original dialog sample.

20. A non-transitory computer-readable storage medium storing instructions which when executed by at least one processor cause the at least one processor to perform:
acquiring an original sample set, the original sample set comprising a plurality of original dialog samples, and each original dialog sample in the plurality of original dialog samples comprising a round of dialog having at least two speaking turns from different speakers;
reconstructing the plurality of original dialog samples to obtain at least an adversarial sample set associated with a perturbation attack scope, each original dialog sample in the plurality of original dialog samples being modified according to the perturbation attack scope to reconstruct a modified dialog sample in the adversarial sample set, the perturbation attack scope including at least one of a current turn scope and a historical turn scope in the at least two speaking turns;
performing a first test of a dialog understanding model by using the original sample set to obtain original evaluation data of the dialog understanding model;
performing a second test of the dialog understanding model by using the adversarial sample set to obtain adversarial evaluation data of the dialog understanding model; and
determining a robustness analysis result of the dialog understanding model according to a change of the adversarial evaluation data with respect to the original evaluation data.
